(19) United States
(12) Patent Application Publication
(10) Pub. No.: US 2023/0345677 A1
(43) Pub. Date: Oct. 26, 2023

(54) COMPACT REAR MOUNTED HEAT EXCHANGERS AND RELATED METHODS

(71) Applicant: Intel Corporation, Santa Clara, CA (US)

(72) Inventors: Shaorong Zhou, Shanghai (CN); Prabhakar Subrahmanyam, San Jose, CA (US); Guocheng Zhang, Shanghai (CN); Tejas Shah, Austin, TX (US); Dongrui Xue, Shanghai (CN)

(21) Appl. No.: 18/344,620

(22) Filed: Jun. 29, 2023

Related U.S. Application Data
(63) Continuation of application No. PCT/CN2023/095587, filed on May 22, 2023.

(30) Foreign Application Priority Data
May 22, 2023 (WO) PCT/CN2023/095587

(51) Int. Cl. H05K 7/20; F28F 9/007

(52) U.S. Cl. CPC H05K 7/20709; F28F 9/007

(57) ABSTRACT

Compact rear mounted modular heat exchangers and related methods are disclosed herein. An example apparatus disclosed herein includes a heat exchanger having an air flow inlet and an air flow outlet, a holder frame to receive a component of a server chassis, and a bracket coupled to the holder frame, the bracket to retain the heat exchanger adjacent a rear of the server chassis.

### FIELD OF THE DISCLOSURE

This disclosure relates generally to compute components and, more particularly, to compact rear mounted modular heat exchangers and related methods.

### BACKGROUND

The use of liquids to cool electronic components is being explored for its benefits over more traditional air cooling systems, as there is an increasing need to address thermal management risks resulting from increased thermal design power in high-performance systems (e.g., CPU and/or GPU servers in data centers, cloud computing, edge computing, and the like). More particularly, relative to the air, liquid has inherent advantages of higher specific heat (when no boiling is involved) and higher latent heat of vaporization (when boiling is involved).

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 11.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 is a perspective view of a prior chassis.

FIG. 18 is a perspective view of the chassis including rear-mounted compact heat exchangers implemented in accordance with teachings of this disclosure.

FIG. 19 is an exploded diagram of an assembly including a heat exchanger of FIG. 18 and a duct.

FIG. 20 is a schematic diagram of a fluid flow path through a power supply of the chassis of FIG. 18 and a heat exchanger of FIG. 17.

FIGS. 21-23 are perspective views of the chassis in various states of assembly.

FIG. 24 is a perspective view of the heat exchanger of FIG. 19 coupled to the power supply of FIG. 22.

FIG. 25 is a perspective view of the chassis of FIG. 18 including an alternative rear-mounted compact heat exchanger implemented in accordance with teachings of this disclosure.

FIG. 26 is a perspective view of a liquid coolant distribution system including the chassis and heat exchangers of FIG. 18 including example cooling system controller circuitry.

FIG. 27 is a block diagram of an example implementation of the cooling system controller circuitry of FIG. 26.

FIG. 28A and FIG. 28B are flowcharts representative of example machine readable instructions and/or example operations that may be executed, instantiated, and/or performed by example programmable circuitry to implement the cooling system controller circuitry of FIG. 27.

FIG. 29 is a block diagram of an example processing platform including programmable circuitry structured to execute, instantiate, and/or perform the example machine readable instructions and/or perform the example operations of FIGS. 28A and 28B to implement the cooling system controller circuitry of FIG. 27.

FIG. 30 is a block diagram of an example implementation of the programmable circuitry of FIG. 29.

FIG. 31 is a block diagram of another example implementation of the programmable circuitry of FIG. 29.

In general, the same reference numbers will be used throughout the drawing(s) and accompanying written description to refer to the same or like parts. The figures are not necessarily to scale.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein “substantially real time” refers to occurrence in a near instantaneous manner recognizing there may be real world delays for computing time, transmission, etc. Thus, unless otherwise specified, “substantially real time” refers to real time+1 second. In some examples used herein, the term “substantially” is used to describe a geometric relationship between two parts that is within three degrees of the stated relationship (e.g., a substantially colinear relationship is within three degrees of being linear, a substantially perpendicular relationship is within three degrees of being perpendicular, a substantially parallel relationship is within three degrees of being parallel, etc.). Similarly, as used herein, a first quantity is “substantially equal” to a second quantity when the first quantity is within 5% of the second quantity.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

As noted above, the use of liquids to cool electronic components is being explored for its benefits over more traditional air cooling systems, as there are increasing needs to address thermal management risks resulting from increased thermal design power in high-performance systems (e.g., CPU and/or GPU servers in data centers, accelerators, artificial intelligence computing, machine learning computing, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic component(s). An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

A liquid cooling system can involve at least one of single-phase cooling or two-phase cooling. As used herein, single-phase cooling (e.g., single-phase immersion cooling) means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase cooling (e.g., two-phase immersion cooling) means the cooling fluid (in this case, a cooling liquid) vaporizes or boils from the heat generated by the electronic components to be cooled, thereby changing from the liquid phase to the vapor phase. The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, indirect cooling and immersion cooling typically involves at least one cooling liquid (which may or may not change to the vapor phase when in use). Example systems, apparatus, and associated methods to improve cooling systems and/or associated cooling processes are disclosed herein.

In recent years, cold plate-based liquid-cooling systems have become more commonly used in compute systems. Cold plate systems cool compute systems via conduction between a heat-producing component, such as a processor, and a cold plate that is cooled via the flow of a liquid coolant therethrough. Coolant is cycled through the cold plate to ensure continued heat transfer from the heat-producing component. The power supplies of compute systems convert alternating current (e.g., from a municipal power grid, etc.) into direct current, which is used by system components. Some current power supplies include cold plate cooling systems. While these systems are effective at cooling the power supplies, such cooling systems can be costly to manufacture. Additionally, the connections in such cooling systems that facilitate the flow of liquid coolant thereto require comparatively large forces to dock the power supply to the compute system, which also increases the cost and complexity of such cooling systems.

Examples disclosed enable the cooling of the power supplies of compute system via rear-mounted compact heat exchangers. Examples disclosed herein are air-to-liquid heat exchangers, which cool the hot exhaust air of a compute system via the heat transfer (e.g., convection, etc.) associated with liquid coolant flowing therein. Examples disclosed herein enable prior air-cooled power supplies to benefit from the efficiency of liquid cooling (e.g., when compared to air-cooling, etc.) via an externally mounted heat exchanger. The externally mounted heat exchangers disclosed herein reduce the likelihood of liquid coolant leakage within a compute system. In some examples disclosed herein, the heat exchangers exhaust air at a temperature that is substantially equal to the temperature of the ambient air of the compute system, which reduces the demand of the cooling system associated with the ambient environment, such as an air-conditioning system of a data center.

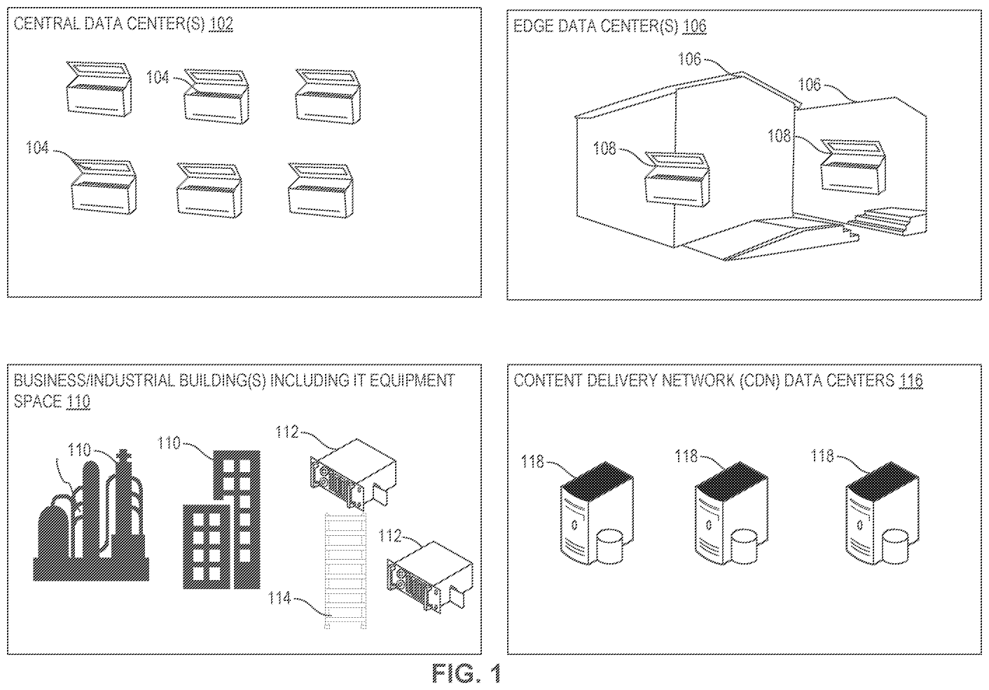

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 includes a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

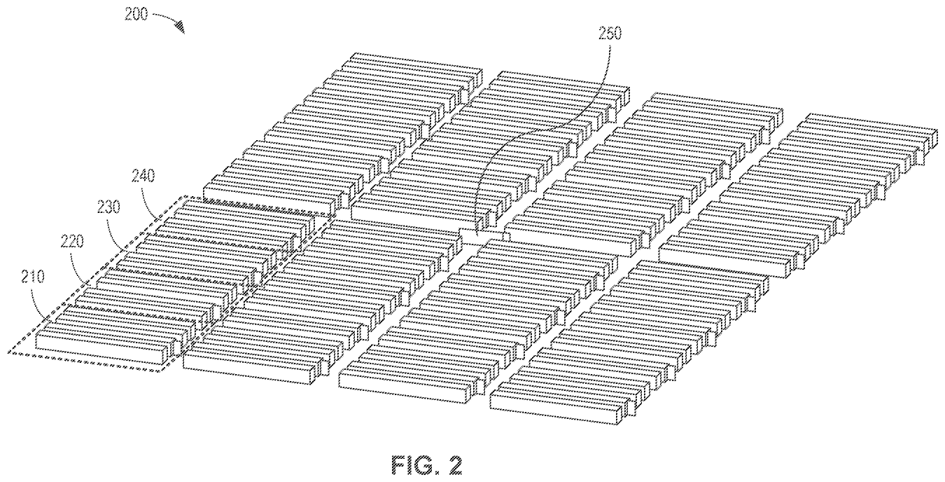

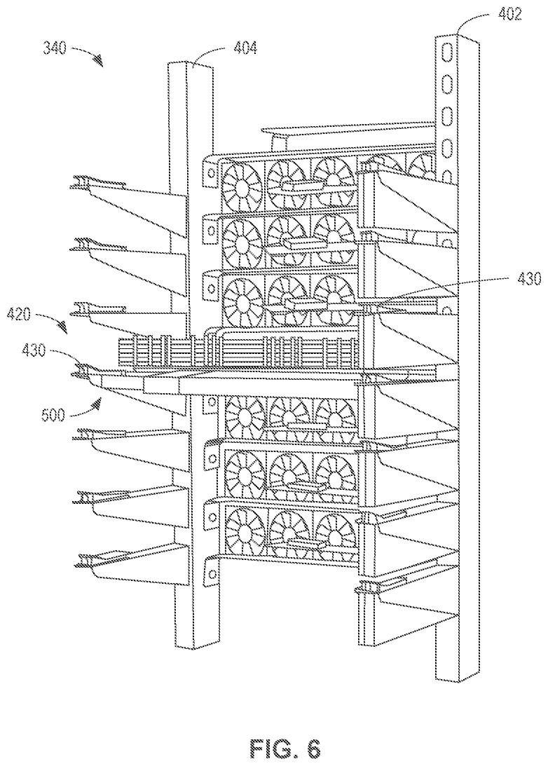

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose programmable circuitry), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first programmable circuitry assigned to one managed node and second programmable circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (programmable circuitry, storage, accelerators, etc.) typically have different refresh rates, greater resource utilization and reduced total cost of ownership may be achieved. For example, a data center operator can upgrade the programmable circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

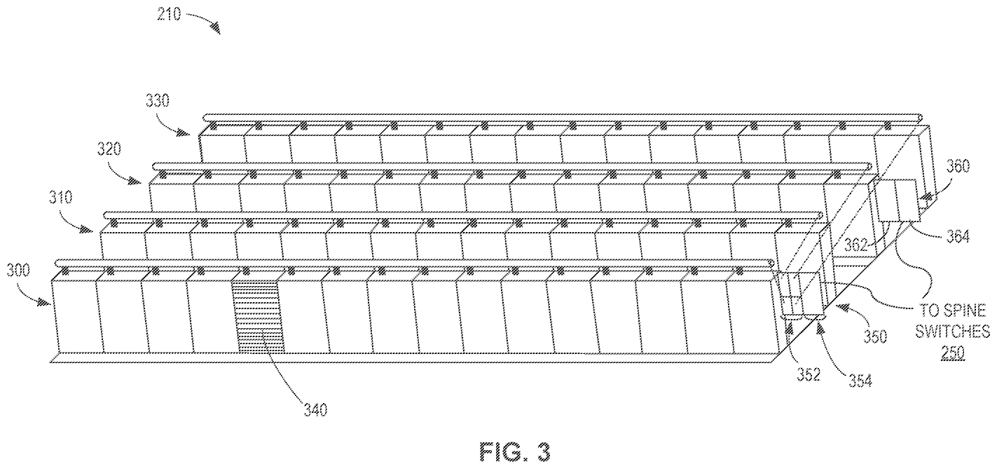

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

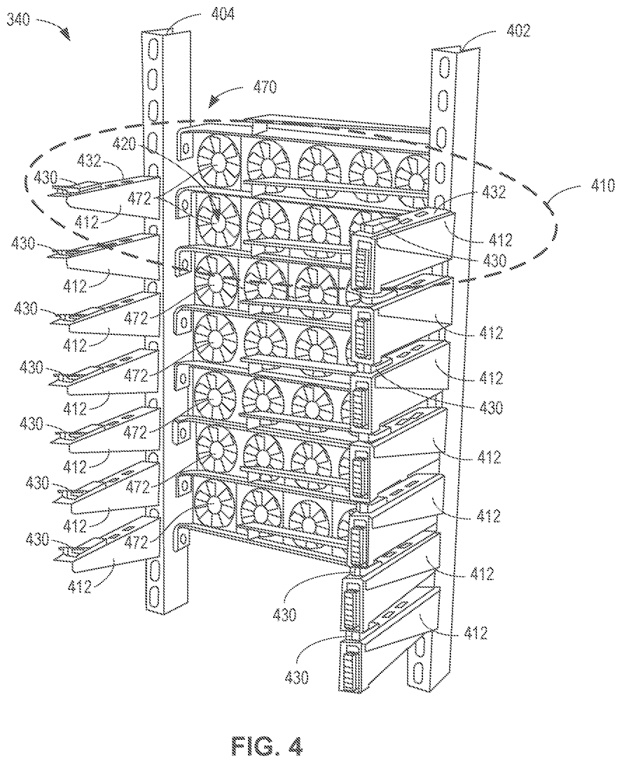

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., programmable circuitry, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

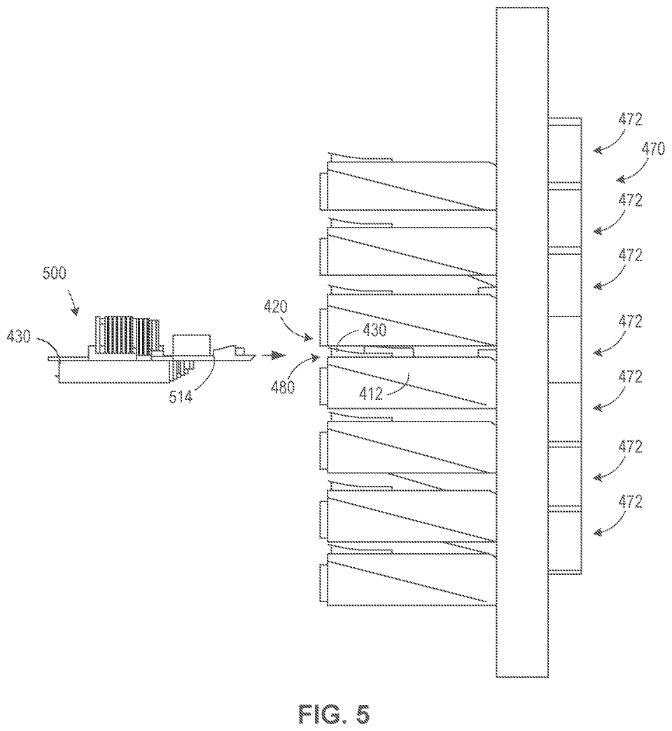

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

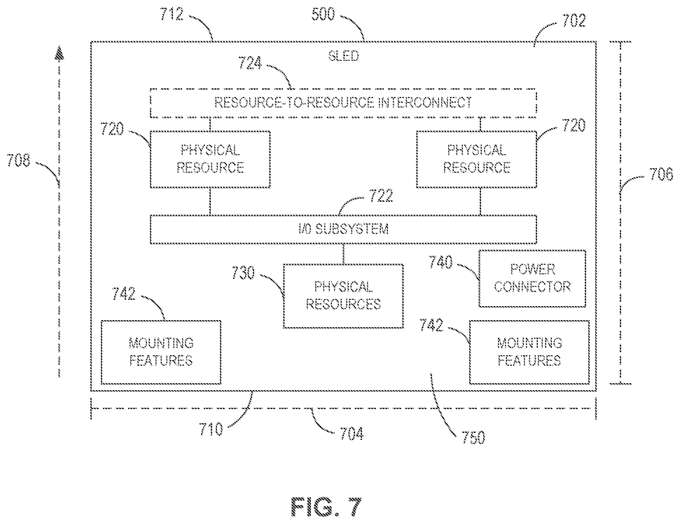

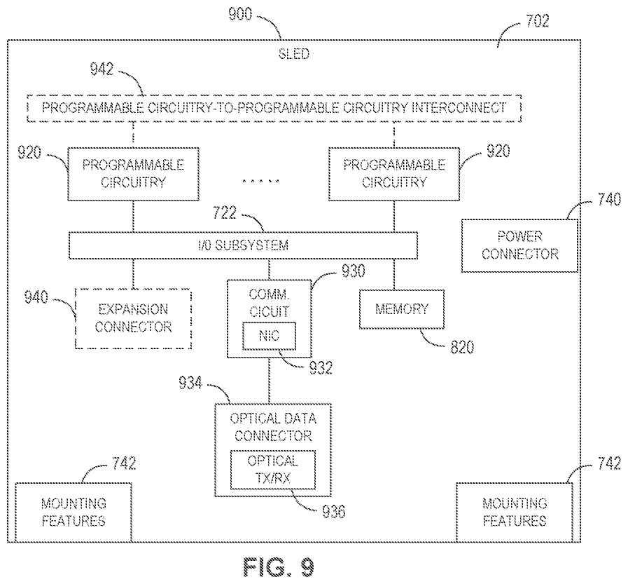

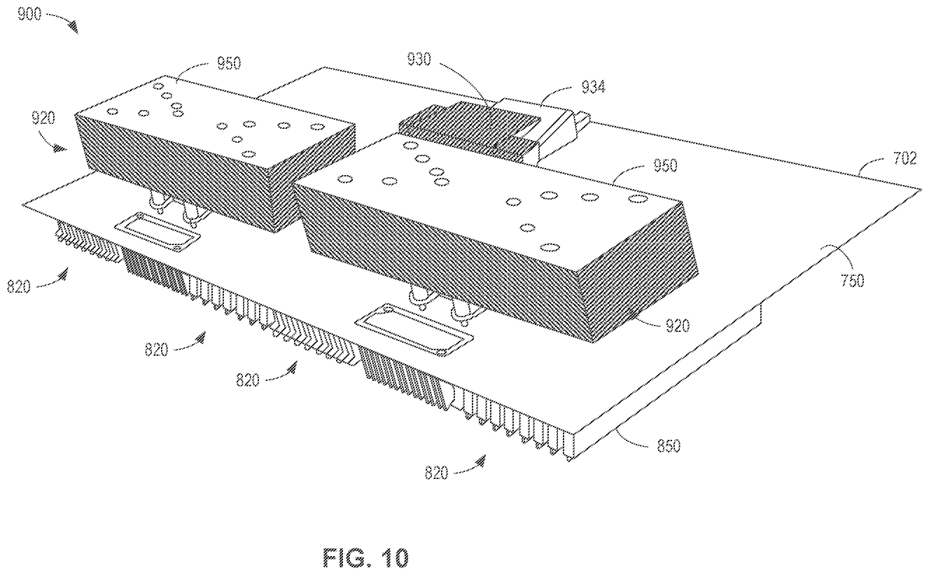

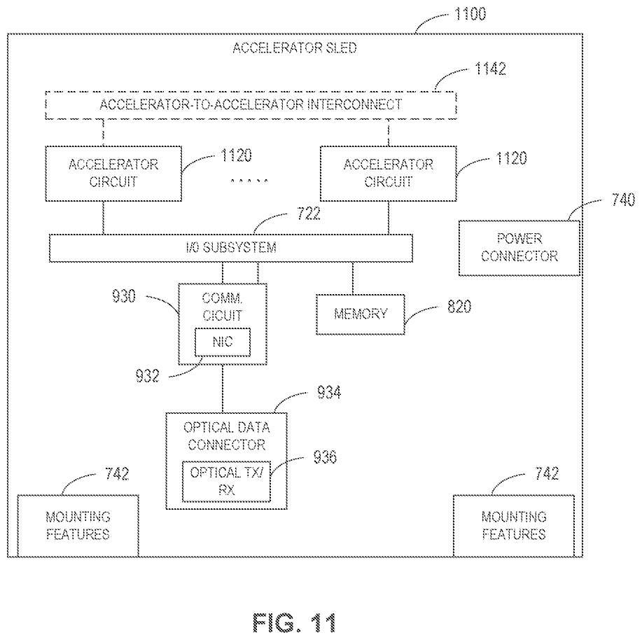

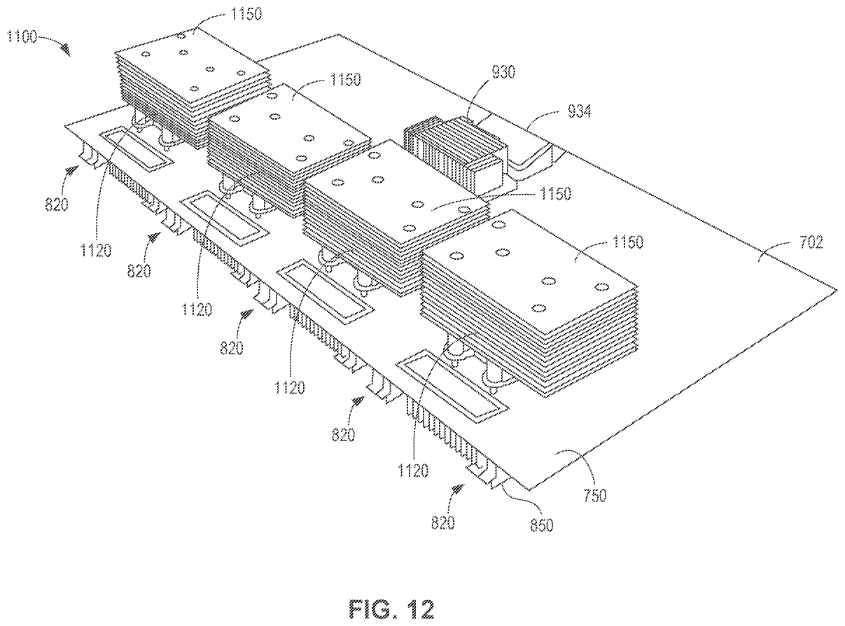

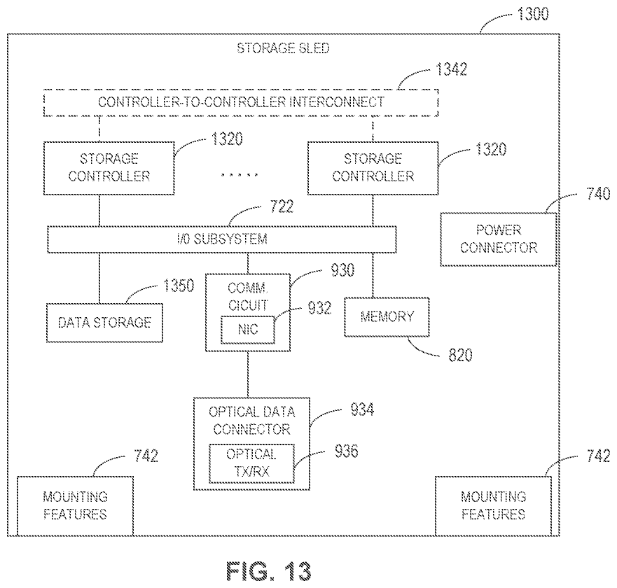

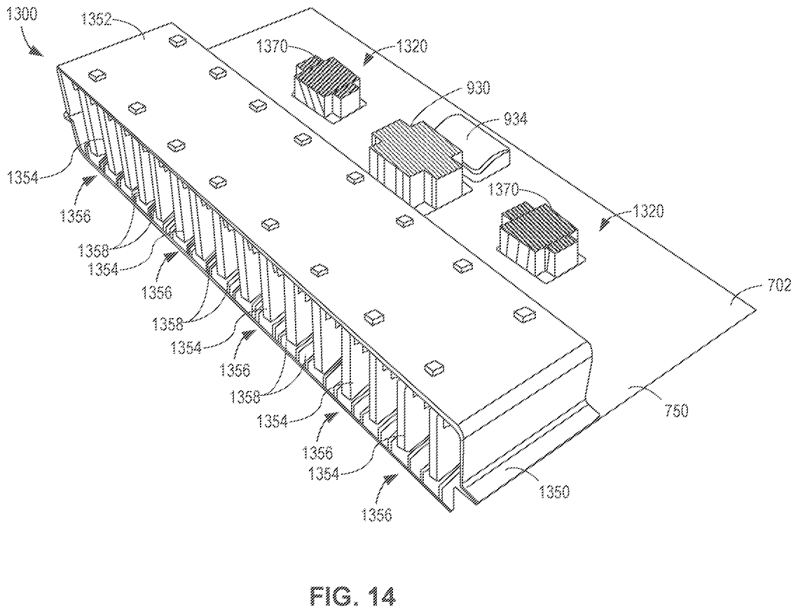

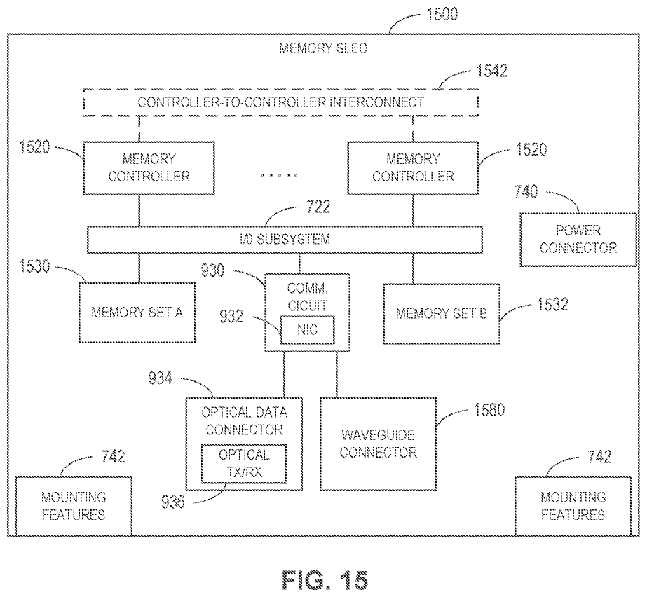

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of programmable circuitry, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processor circuitry in examples in which the sled 500 is implemented as a compute sled, as accelerator co-processor circuitry or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

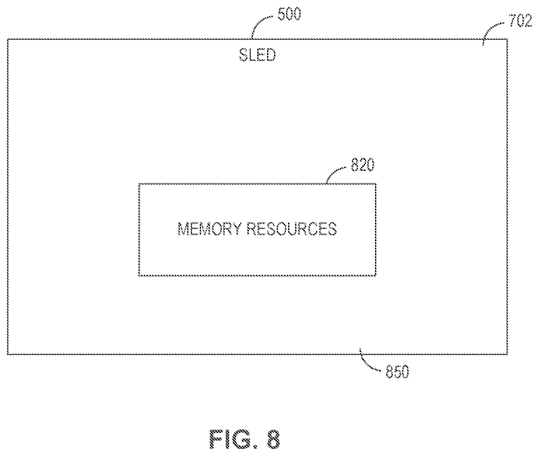

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of programmable circuitry 920 (see FIG. 9), and power is routed from the voltage regulators to the programmable circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 500 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include programmable circuitry 920. Although only two blocks of programmable circuitry 920 are shown in FIG. 9, it should be appreciated that the compute sled 900 may include additional programmable circuits 920 in other examples. Illustratively, the programmable circuitry 920 corresponds to high-performance processor circuitry 920 and may be configured to operate at a relatively high power rating. Although the high-performance programmable circuitry 920 generates additional heat operating at power ratings greater than typical processor circuitry (which operate at around 155-230 W), the enhanced thermal cooling characteristics of the chassis-less circuit board substrate 702 discussed above facilitate the higher power operation. For example, in the illustrative example, the programmable circuitry 920 is configured to operate at a power rating of at least 250 W. In some examples, the programmable circuitry 920 may be configured to operate at a power rating of at least 350 W.

In some examples, the compute sled 900 may also include a programmable circuitry-to-programmable circuitry interconnect 942. Similar to the resource-to-resource interconnect 724 of the sled 500 discussed above, the programmable circuitry-to-programmable circuitry interconnect 942 may be implemented as any type of communication interconnect capable of facilitating programmable circuitry-to-programmable circuitry interconnect 942 communications. In the illustrative example, the programmable circuitry-to-programmable circuitry interconnect 942 is implemented as a high-speed point-to-point interconnect (e.g., faster than the I/O subsystem 722). For example, the programmable circuitry-to-programmable circuitry interconnect 942 may be implemented as a QuickPath Interconnect (QPI), an UltraPath Interconnect (UPI), or other high-speed point-to-point interconnect dedicated to programmable circuitry-to-programmable circuitry communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processor circuits, or included on a multichip package that also contains one or more processor circuits. In some examples, the NIC 932 may include a local processor circuit (not shown) and/or a local memory (not shown) that are both local to the NIC 932. In such examples, the local processor circuit of the NIC 932 may be capable of performing one or more of the functions of the programmable circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the programmable circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processor circuitry, memory devices, storage devices, and/or accelerator circuits including, for example, field programmable gate arrays (FPGA), application-specific integrated circuits (ASICs), security co-processor circuits, graphics processing units (GPUs), machine learning circuits, or other specialized processor circuits, controllers, devices, and/or circuits.

Referring now to FIG. 10, an illustrative example of the compute sled 900 is shown. As shown, the programmable circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor circuit socket), holders, or brackets. In some cases, some of the electrical components may be directly mounted to the chassis-less circuit board substrate 702 via soldering or similar techniques.

As discussed above, the separate programmable circuitry 920 and the communication circuit 930 are mounted to the top side 750 of the chassis-less circuit board substrate 702 such that no two heat-producing, electrical components shadow each other. In the illustrative example, the programmable circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the programmable circuitry 920 located on the top side 750 via the I/O subsystem 722. Because the chassis-less circuit board substrate 702 is implemented as a double-sided circuit board, the memory devices 820 and the programmable circuitry 920 may be communicatively coupled by one or more vias, connectors, or other mechanisms extending through the chassis-less circuit board substrate 702. Different programmable circuitry 920 (e.g., different processor circuitry) may be communicatively coupled to a different set of one or more memory devices 820 in some examples. Alternatively, in other examples, different programmable circuitry 920 (e.g., different processor circuitry) may be communicatively coupled to the same ones of the memory devices 820. In some examples, the memory devices 820 may be mounted to one or more memory mezzanines on the bottom side of the chassis-less circuit board substrate 702 and may interconnect with a corresponding programmable circuitry 920 through a ball-grid array.

Different programmable circuitry 920 (e.g., different processor circuitry) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the programmable circuitry heatsinks 950 include cooling fans attached thereto. That is, the heatsinks 950 may be fan-less heatsinks. In some examples, the heatsinks 950 mounted atop the programmable circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor circuitry, co-processor circuitry, compute circuit, or other device capable of performing compute or processing operations. For example, the accelerator circuits 1120 may be implemented as, for example, field programmable gate arrays (FPGA), application-specific integrated circuits (ASICs), security co-processor circuitry, graphics processing units (GPUs), neuromorphic processor units, quantum computers, machine learning circuits, or other specialized processor circuitry, controllers, devices, and/or circuits.

In some examples, the accelerator sled 1100 may also include an accelerator-to-accelerator interconnect 1142. Similar to the resource-to-resource interconnect 724 of the sled 500 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to programmable circuitry-to-programmable circuitry communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 500. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of programmable circuitry, controller, or control circuit capable of controlling the storage and retrieval of data into the data storage 1350 based on requests received via the communication circuit 930. In the illustrative example, the storage controllers 1320 are implemented as relatively low-power programmable circuitry or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to programmable circuitry-to-programmable circuitry communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 340. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor circuit socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of programmable circuitry, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to programmable circuitry-to-programmable circuitry communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

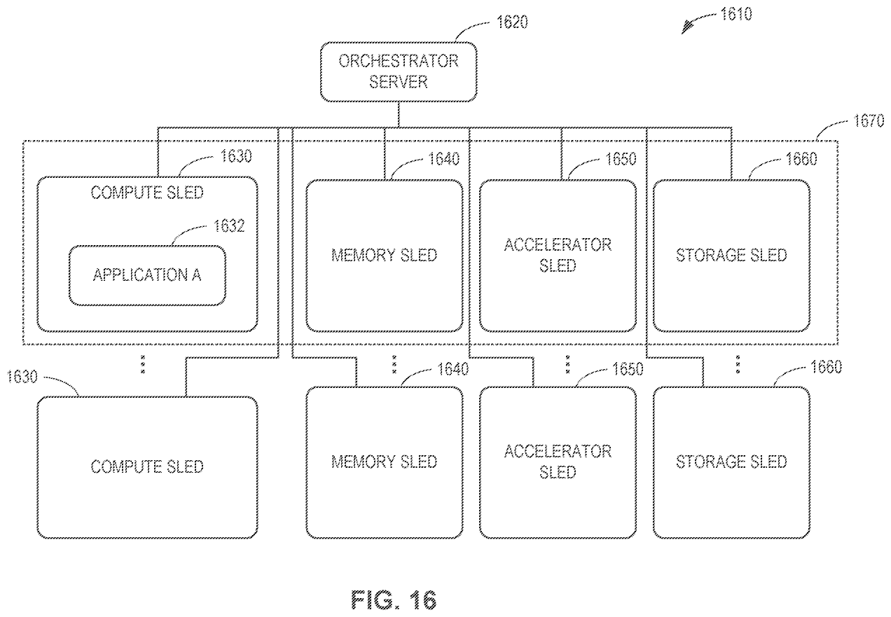

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., programmable circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the accelerator sled 1100), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as programmable circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of programmable circuitry or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

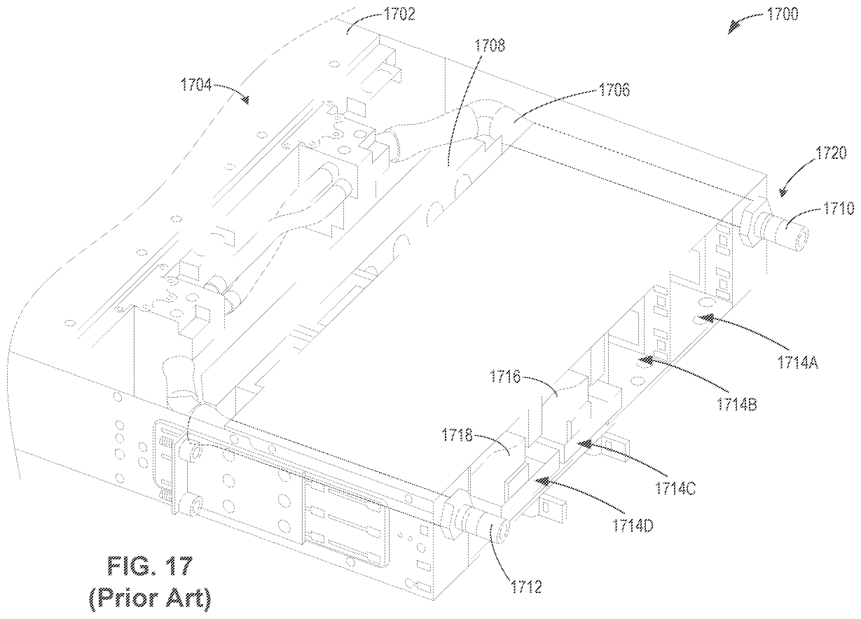

FIG. 17 is a perspective view of a prior chassis 1700. In FIG. 17, the chassis 1700 includes a frame 1702 that includes compute components 1704 and a cooling system 1706. In FIG. 17, the cooling system 1706 includes a manifold 1708, receives liquid coolant from an inlet 1710, and exhausts liquid coolant from an outlet 1712. In FIG. 17, the chassis 1700 includes a first slot 1714A, a second slot 1714B, a third slot 1714C, and a fourth slot 1714D. In FIG. 17, a first power supply assembly 1716 is disposed within the third slot 1714C, and a second power supply assembly 1718 is disposed within the fourth slot 1714D. The chassis 1700 can be a component of a server pod (e.g., the server pod 210 of FIG. 2, etc.), a server rack (e.g., the server rack 340 of FIGS. 3 and/or 4, etc.), and/or otherwise part of a server system (e.g., a server farm, etc.).

The chassis 1700 is an assembly that houses the compute components 1704. In FIG. 17, the chassis 1700 includes the frame 1702 that structurally/mechanically supports the compute components 1704 and the cooling system 1706. The compute components 1704 can include one or more processor units (e.g., one or more CPUs, one or more GPUs, one or more accelerators, one or more FPGAs, etc.) and/or related compute components (e.g., permanent memory, temporary memory, etc.).

The operation of the compute components 1704 in the chassis 1700 generates heat, which is dissipated via the operation of the cooling system 1706. The cooling system 1706 is a liquid cooling system that includes an internal flow path that distributes liquid coolant to various locations within the frame 1702 of the chassis 1700. The inlet 1710 and the outlet 1712 are ports that permit liquid coolant to enter and leave the cooling system 1706. In FIG. 17, the cooling system 1706 receives comparatively cool liquid coolant via the inlet 1710 and exhausts (e.g., expels, etc.) comparatively warm liquid coolant via the outlet 1712. In FIG. 17, the inlet 1710 and the outlet 1712 are disposed on opposite sides of an example rear 1720 of the chassis 1700. The cooling system 1706 includes one or more cold plates (not illustrated) that dissipate heat generated by the compute components 1704.

In FIG. 17, the power supply assemblies 1716, 1718 receive alternating current power from a power source of the chassis 1700, convert the received current to direct current power and provide the direct current power to the compute components 1704. In FIG. 17, the power supply assemblies 1716, 1718 are disposed within the third slot 1714C, and the fourth slot 1714D, respectively. The chassis 1700 includes the first slot 1714A and the second slot 1714B, which can permit additional power supply assemblies to the chassis 1700.

The operation of the power supply assembly 1716, 1718 generates heat, which is dissipated by the cooling system 1706. The manifold 1708 provides liquid coolant, which flows through internal flow paths of the power supply assemblies 1716, 1718, and dissipates heat therefrom via convection. Such internal flow paths of the power supply assemblies 1716, 1718 can be costly to design and manufacture, which increases the design time and monetary cost of the power supply assemblies 1716, 1718. Furthermore, the coupling of internal flow paths of the power supply assemblies 1716, 1718 can increase the docking force required to couple to power supply assembly 1716, 1718 to the chassis 1700 and/or the cooling system 1706 (e.g., to ensure a sealed connection for liquid coolant to flow therethrough, etc.). This high docking force increases the structural demands on the power supply assembly 1716, 1718 and the chassis 1700, which can also increase costs. Additionally, the internal flow paths of the power supply assemblies 1716, 1718 increase the number of locations in which the cooling system 1706 can leak, which can increase the service requirements of the chassis 1700.

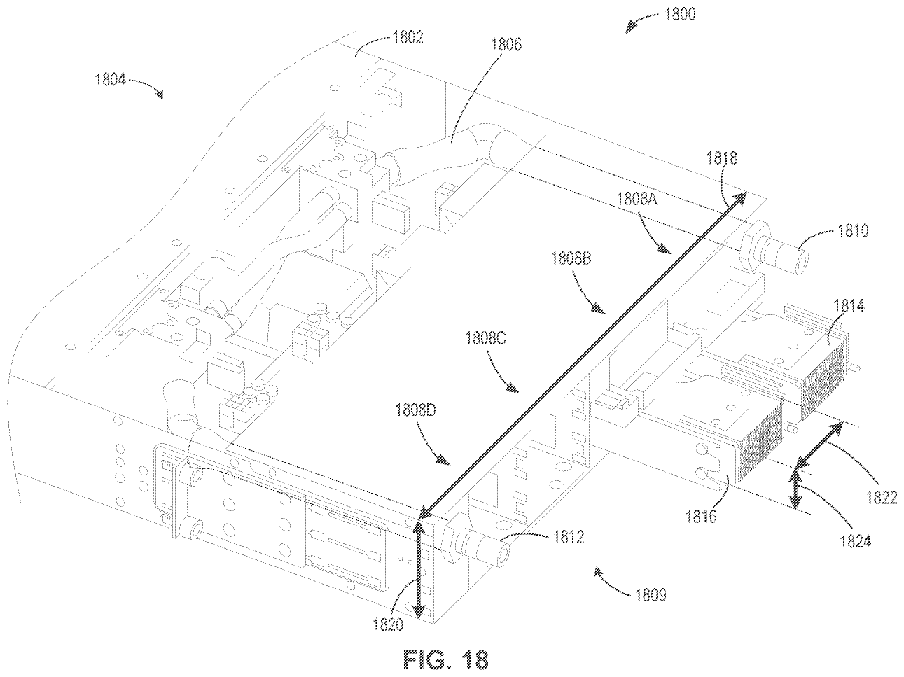

FIG. 18 is a perspective view of an example chassis 1800 including rear-mounted compact heat exchangers implemented in accordance with teachings of this disclosure. In the illustrated example of FIG. 18, the chassis 1800 includes a frame 1802 that includes example compute components 1804, and an example cooling system 1806. In the illustrated example of FIG. 18, the frame 1802 includes an example first slot 1808A, an example second slot 1808B, an example third slot 1808C, and an example fourth slot 1808D disposed on an example rear 1809 of the chassis 1800. In the illustrated example of FIG. 18, the cooling system 1806 receives liquid coolant from an example inlet 1810 and exhausts liquid coolant from an example outlet 1812. In the illustrated example of FIG. 18, an example first heat exchanger 1814 is disposed externally to and behind the first slot 1808A, and an example second heat exchanger 1816 disposed externally to and behind the second slot 1808B.

The frame 1802 structurally/mechanically supports the compute components 1804 and the cooling system 1806. In the illustrated example of FIG. 18, the frame 1802 is a rectangular prism. In other examples, the frame 1802 can have any other suitable shape (e.g., a different prism, a cube, a cylinder, etc.). In some examples, the frame 1802 can include one or more features (e.g., fasteners, brackets, holes, slots, etc.) that permit the chassis 1800 to be coupled to a rack (e.g., the server rack 340 of FIGS. 3 and/or 4, etc.). In some examples, the frame 1802 can be absent. In some such examples, teachings of this disclosure are implemented in conjunction with a chassis-less sled.

The compute components 1804 can include one or more processor units (e.g., one or more CPUs, one or more GPUs, one or more accelerators, one or more FPGAs, etc.) and/or related compute components (e.g., permeant memory, temporary memory, etc.). The compute components 1804 can be arranged in any suitable configuration, including a shadowed configuration (e.g., a shadowed form factor, etc.) and/or a spread core configuration (e.g., a spread core form factor, etc.). In some examples, the compute components 1804 can have one or more cold plates that permit heat to be dissipated therefrom by the cooling system 1806 via liquid coolant flow (e.g., convection, etc.). In other examples, the compute components 1804 can be cooled via the cooling system 1806 in any other suitable manner.

In the illustrated example of FIG. 18, the example cooling system 1806 is similar to the cooling system 1706 of FIG. 17, except that the example cooling system 1806 of FIG. 18 does not provide liquid coolant for the cooling of the power supplies in the chassis 1800. In the illustrated example of FIG. 18, the cooling system 1806 is a liquid cooling system (e.g., includes an internal flow path for liquid coolant that cools the compute components 1804 via convection, etc.). In other examples, the cooling system 1806 can be implemented via a fully air-cooled system (e.g., the cooling system 1806 can include one or more fans, etc.) and/or an immersion cooling system (e.g., part of the chassis 1800 is submerged in liquid coolant, etc.). In some examples, the liquid coolant of the cooling system 1806 can be any suitable liquid, including water, an ethylene glycol solution, a propylene glycol solution, and a dielectric fluid (e.g., mineral oil, castor oil, hexane, silicone oil, distilled water, a fluorinated ketone, a perfluorinated compound, etc.).

In the illustrated example of FIG. 18, the rear 1809 of the frame 1802 and the chassis 1800 include the slots 1808A, 1808B, 1808C, 1808D. The slots 1808A, 1808B, 1808C, 1808D are openings within the frame 1802 that enable one or more power supplies to be coupled to the frame 1802. In the illustrated example of FIG. 18, the slots 1808A, 1808B, 1808C, 1808D have substantially the same size (e.g., a same length, a same width, a same height, a same depth, etc.). In other examples, some or all of the slots 1808A, 1808B, 1808C, 1808D can have different dimensions (e.g., a different length, a different width, a different height, a different depth, etc.). In the illustrated example of FIG. 18, the slots 1808A, 1808B, 1808C, 1808D are aligned along the rear 1809 of the chassis 1800. In other examples, the 1808A, 1808B, 1808C, 1808D can have any other suitable configuration. In some examples, the slots 1808A, 1808B, 1808C, 1808D are ports of the chassis 1800 that can receive one or more corresponding power supplies. While the chassis 1800 is depicted as having four slots (e.g., the slots 1806A, 1806B, 1806C, 1806D, etc.), in other examples, the chassis 1800 can include any other suitable number of slots (e.g., one slot, two slots, four slots, etc.).

The inlet 1810 and the outlet 1812 are ports that permit liquid coolant to enter and leave the cooling system 1806. In the illustrated example of FIG. 18, the inlet 1810 and the outlet 1812 are disposed on opposite sides of the rear 1809 of chassis 1800. In other examples, the inlet 1810 and the outlet 1812 can be disposed at any other suitable locations (e.g., another location on the rear 1809 of the chassis 1800, on a side of the chassis 1800, a front of the chassis 1800, etc.). In other examples, the inlet 1810 and/or the outlet 1812 can be absent (e.g., if the cooling system 1806 is an air cooling system, etc.). In some examples, during the operation of the chassis 1800 and the associated components therein, the coolant enters the cooling system 1806 via the inlet and leaves the cooling system 1806 via the exhaust, at a constant and equal or substantially constant and equal rate, which enables the continuous cooling of the compute components 1804.

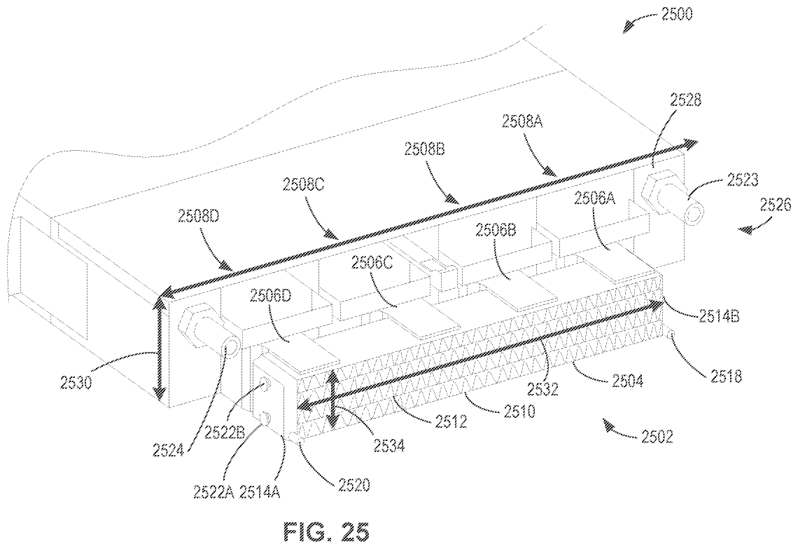

The heat exchangers 1814, 1816 are compact air-to-liquid coolant coolers implemented in accordance with teachings of this disclosure. The heat exchangers 1814, 1816 cool the exhaust of some, or all of the power supply assemblies associated with the chassis 1800. In the illustrated example of FIG. 18, the first heat exchanger 1814 is disposed externally to and behind the first slot 1808A and an example second heat exchanger 1816 is disposed externally to and behind the second slot 1808B. In the illustrated example of FIG. 18, the first heat exchanger 1814 is separate and distinct from the second heat exchanger 1816. In other examples, the first heat exchanger 1814 and the second heat exchanger 1816 can be integral. An example chassis including integral heat exchangers implemented in accordance with teachings of this disclosure is described below in conjunction with FIG. 25.

The heat exchangers 1814, 1816 receive hot air flow (e.g., comparatively hot airflow, etc.) moving towards the rear of the chassis 1800 (e.g., from power supplies associated with the chassis 1800, etc.), cool the airflow, and expel (e.g., exhaust, etc.) the cooled air into the ambient environment of the chassis 1800 (e.g., an aisle of a data center, etc.). In the illustrated example of FIG. 18, the first heat exchanger 1814 receives hot exhaust flow from a power supply associated with the first slot 1808A and the second heat exchanger 1816 receives hot exhaust flow from a power supply associated with the second slot 1808B.

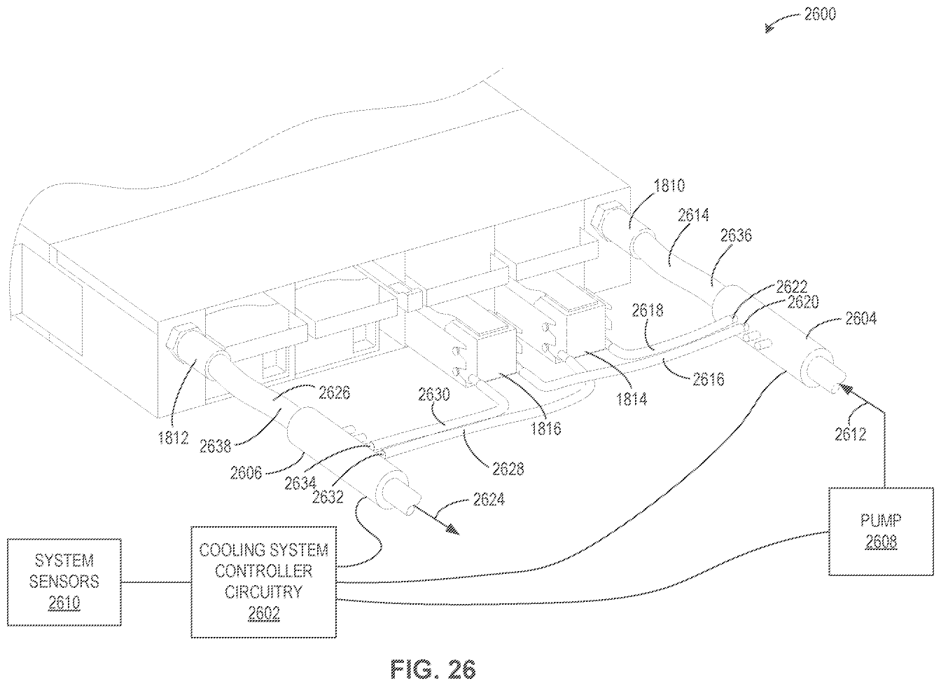

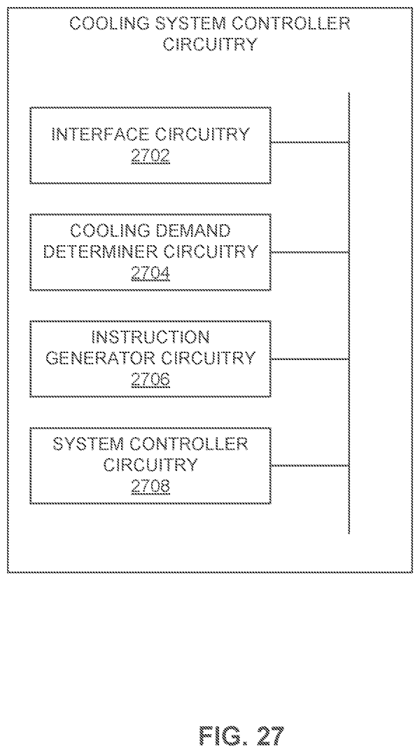

In some examples, the heat exchangers 1814, 1816 include internal flow paths (e.g., pipes, channels, tubing, etc.) that contain liquid coolant that absorbs heat from the airflow through the heat exchangers 1814, 1816. In some such examples, the internal flow paths of the heat exchangers 1814, 1816 receive liquid coolant from the same source as the cooling system 1806 of the chassis 1800, etc.). In other examples, the internal flow paths of the heat exchangers 1814, 1816 can receive liquid coolant from a different source than the cooling system 1806. In some examples, the flow of liquid coolant through the heat exchangers 1814, 1816 can be controlled via one or more controllable features (e.g., valves, pipes, etc.). In some such examples, the first heat exchanger 1814 can have a different flow rate of liquid coolant than the second heat exchanger 1816. An example control system for regulating the flow of coolant through the heat exchangers 1814, 1816 is described below in conjunction with FIG. 26. Example operations for regulating the flow of coolant through the heat exchangers 1814, 1816 are described below in conjunction with FIG. 27.

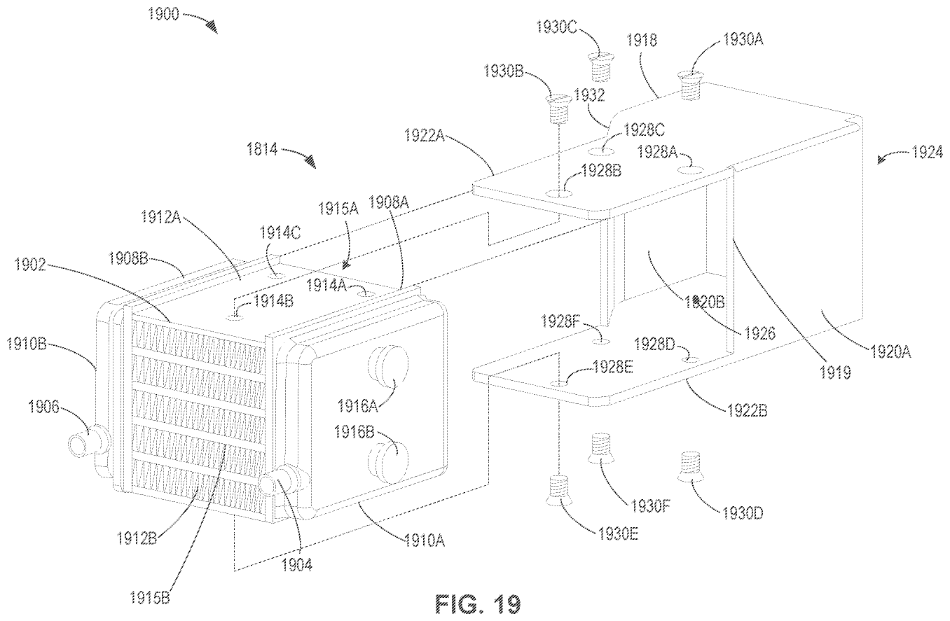

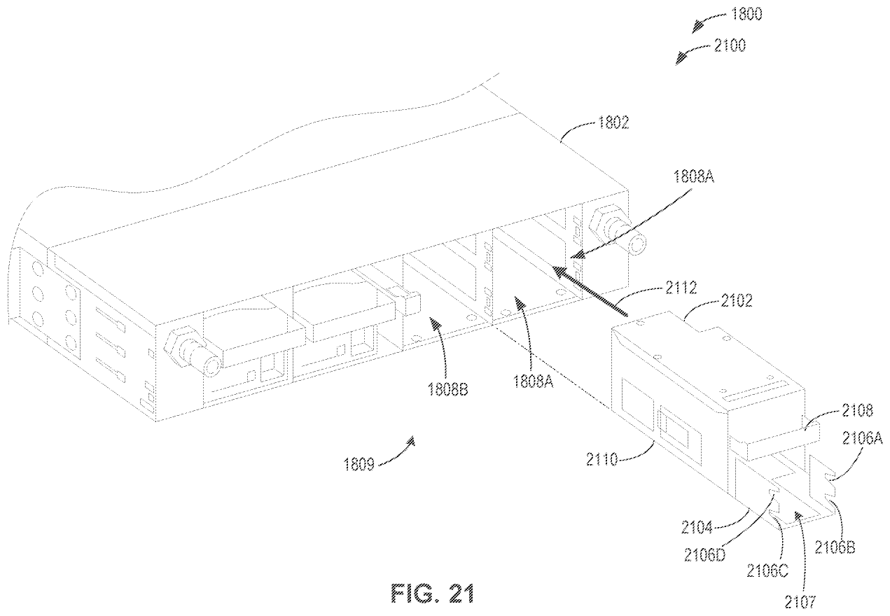

In some examples, the interiors of the first heat exchanger 1814 and/or the second heat exchanger 1816 include internal structures (e.g., fins, channels, etc.) that increase the surface area of the heat exchangers to increase the rate of heat transfer between the air flow from the chassis 1800 and the heat exchangers 1814, 1816. In other examples, such internal structures are absent. The first heat exchanger 1814 is described below in additional detail in conjunction with FIGS. 19, 20, and 24. An example process of assembling the chassis 1800 and the heat exchangers 1814, 1816 is described below in conjunction with FIGS. 21-23.

In the illustrated example of FIG. 18, the third slot 1808C and the fourth slot 1808D do not have corresponding heat exchangers coupled thereto. In some such examples, the power supply assemblies associated with the slots 1808C, 1808D can be cooled via the circulation of coolant from the cooling system 1806. Additionally or alternatively, the power supply assemblies associated with the slots 1808C, 1808D can be air cooled and can exhaust hot air at the rear 1809 of the frame 1802 and the chassis 1800. In other examples, the third slot 1808C and the fourth slot 1808D do not include corresponding power supply assemblies. It should be appreciated that one or both of the third slot 1808C and/or the fourth slot 1808D can include heat exchanger(s) similar to the heat exchangers 1814, 1816. Similarly, chassis with different numbers of slots than the chassis 1800 of FIG. 18 can accommodate a corresponding quantity of heat exchangers similar to heat exchangers 1814, 1816.

In the illustrated example of FIG. 18, the chassis 1800 has an example chassis width 1818 and an example chassis height 1820. In the illustrated example of FIG. 18, the first heat exchanger 1814 has an example heat exchanger width 1822 and an example heat exchanger height 1824. In the illustrated example of FIG. 18, the ratio of the chassis width 1818 and the heat exchanger width 1822 is approximately 6.6. In other examples, the ratio of the chassis width 1818 and the heat exchanger width 1822 can be any suitable value between 3 and 10. In the illustrated example of FIG. 18, the ratio of the chassis height 1820 and the heat exchanger height 1824 is approximately 2.25. In other examples, the ratio between the chassis height 1820 and the heat exchanger height 1824 can be any suitable value between 1 and 4. In some examples, the standardized size of a 1U server chassis is approximately 44.5 millimeters in height, 845 millimeters in width, and between 800 and 950 millimeters in length. In some such examples, heat exchangers implemented in accordance with the teachings of this disclosure can be approximately 40 millimeters in height, 30 millimeters in width, and between 75 millimeters in length. In the illustrated example of FIG. 18, the second heat exchanger 1814 has the same dimensions as the first heat exchanger 1814 (e.g., the second heat exchanger 1814 has the heat exchanger width 1822 and the heat exchanger height 1824, etc.). In other examples, the second heat exchanger 1816 can have different dimensions than the first heat exchanger 1814.

FIG. 19 is an exploded diagram of an example heat exchanger assembly 1900 including the first heat exchanger 1814 of FIG. 18. In the illustrated example of FIG. 19, the first heat exchanger 1814 includes an example body 1902, an example heat exchanger coolant inlet 1904, an example heat exchanger coolant outlet 1906, an example first rail 1908A, an example second rail 1908B, an example first side portion 1910A, and an example second side portion 1910B. In the illustrated example of FIG. 19, the rails 1908A, 1908B define an example first mounting surface 1912A and an example second mounting surface 1912B. In the illustrated example of FIG. 19, the first mounting surface 1912A includes an example first opening 1914A, an example second opening 1914B, and an example third opening 1914C. In the illustrated example of FIG. 19, the first side portion 1910A includes an example first bracket fastener 1916A and an example second bracket fastener 1916B.

The heat exchanger assembly 1900 also includes an example duct 1918 having an example flow conduit 1919 defined by an example first side wall 1920A, an example second side wall 1920B, an example first plate 1922A, and an example second plate 1922B. In the illustrated example of FIG. 19, the side walls 1920A, 1920B define an example conduit inlet 1924 and an example duct conduit outlet 1926. In the illustrated example of FIG. 19, the first plate 1922A includes an example first hole 1928A, an example second hole 1928B, and an example third hole 1928C and the second plate 1922B includes an example fourth hole 1928D, an example fifth hole 1928E, and an example sixth hole 1928F. In the illustrated example of FIG. 19, the heat exchanger assembly 1900 includes an example first fastener 1930A, an example second fastener 1930B, an example third fastener 1930C, an example fourth fastener 1930D, an example fifth fastener 1930E, and an example sixth fastener 1930F.

In the illustrated example of FIG. 19, the first heat exchanger 1814 is composed of the body 1902, the side portion 1910A, and the side portion 1910B. In the illustrated example of FIG. 19, the side portions 1910A, 1910B extend from opposites sides of the body 1902. In the illustrated example of FIG. 19, the body 1902 of the first heat exchanger 1814 is generally shaped like a rectangular prism and the side portions 1910A, 1910B extend from the comparatively smaller ends of the body 1902. In other examples, the body 1902 can have any other suitable shape (e.g., a different prism, a cylinder, etc.). In the illustrated example of FIG. 19, the body 1902 includes an example air flow inlet 1915A and the example air flow outlet 1915B, which enable exhaust air flow from the duct 1918 to pass through the first heat exchanger 1814. In the illustrated example, the air flow inlet 1915A is formed on the opposite side of the body 1902 as the air flow outlet 1915B.

The heat exchanger coolant inlet 1904 and the heat exchanger coolant outlet 1906 are ports that permit liquid coolant to enter and leave the internal flow path of the first heat exchanger 1814. In the illustrated example of FIG. 18, the heat exchanger coolant inlet 1904 and the heat exchanger coolant outlet 1906 are on the same side of the body 1902 and are adjacent to the air flow outlet 1915B. In the illustrated example of FIG. 19, the heat exchanger coolant inlet 1904 is disposed on the first side portion 1910A, and the heat exchanger coolant outlet 1906 is disposed on the second side portion 1910B. In other examples, the heat exchanger coolant inlet 1904 and the heat exchanger coolant outlet 1906 can be disposed at any other suitable locations (e.g., other location(s) on the side portions 1910A, 1910B, on a side of the body 1902, on the rear of the body 1902, etc.). In some examples, during the operation of the first heat exchanger 1814, the coolant enters the first heat exchanger 1814 via the heat exchanger coolant inlet 1904 and leaves the first heat exchanger 1814 via the heat exchanger coolant outlet 1906, at a constant and equal or substantially constant and equal rate.

In the illustrated example of FIG. 19, the side portions 1910A, 1910B have a filleted interface with the body 1902 and the rails 1908A, 1908B. In other examples, the side portions 1910A, 1910B can have any other suitable interface with the body 1902 and the rails 1908A, 1908B (e.g., chamfering, billeting, etc.). In other examples, the side portions 1910A, 1910B can be flush with the surfaces of the body 1902. The first rail 1908A separates the body 1902 and the first side portion 1910A and the second rail 1908B separates the body 1902 and the second side portion 1910B. The rails 1908A, 1908B are mechanical bosses that protrude from the body 1902. In the illustrated example of FIG. 19, the rails 1908A, 1908B extend around the entirety of the body 1902. In other examples, the rails 1908A, 1908B can be extended only on the top and/or the bottom of the body 1902. In some examples, one or both of the rails 1908A, 1908B can be absent.

In some examples, the body 1902, the side portions 1910A, 1910B, and the rails 1908A, 1908B are integral (e.g., composed of a single part, etc.). In some such examples, the first heat exchanger 1814 can be manufactured via additive manufacturing, casting, and/or negative machining. In other examples, the body 1902, the side portions 1910A, 1910B, and the rails 1908A, 1908B can be manufactured separately and assembled via one or more fasteners, one or more press fits, one or more welds, one or more chemical adhesives, and/or a combination thereof.

The first side portion 1910A includes the first bracket fastener 1916A and an example second bracket fastener 1916B that enables the heat exchanger assembly 1900 to be coupled to a chassis (e.g., the chassis 1800 of FIG. 18, etc.). In the illustrated example of FIG. 19, the first bracket fastener 1916A and an example second bracket fastener 1916B can be tightened (e.g., decreasing the distance between the head of the respective bracket fastener and the side portion 1910A, etc.) and/or loosened (e.g., increasing the distance between the head of the respective bracket fastener and the side portion 1910A, etc.). In some examples, to couple the heat exchanger assembly 1900 to a chassis, the bracket fasteners 1916A, 1916B can be loosened, to facilitate the receiving of a bracket associated with the chassis between the side portion of the head of the bracket fasteners 1916A, 1916B. In some such examples, after receiving the bracket, the bracket fasteners 1916A, 1916B can be tightened to retain the heat exchanger assembly 1900 to the chassis via a frictional interface (e.g., a clamp interface, etc.). Additionally or alternatively, the heat exchanger assembly 1900 can be coupled to a chassis in any other suitable manner. In some examples, the second side portion 1910B can include bracket fasteners similar to the bracket fasteners 1916A, 1916B.

In the illustrated example of FIG. 19, the duct 1918 is a mechanical structure that is configured to act as a flow path for exhaust flow from a chassis (e.g., the chassis 1800 of FIG. 18, etc.) to the first heat exchanger 1814. In the illustrated example of FIG. 19, the duct 1918 is an integral part (e.g., a single piece, etc.). In other examples, the duct 1918 can be composed of multiple parts (e.g., the plates 1922A, 1922B can be separate components from the flow conduit 1919, etc.). The duct 1918 can be composed of a metal, a heat-resistant plastic, a polymer, and/or a combination thereof. In some examples, the duct 1918 can be insulated to reduce heat transfer from the interior of the flow conduit 1919 into the ambient environment of the first heat exchanger 1814.

In the illustrated example, the duct 1918 defines the flow conduit 1919, which extends between the conduit inlet 1924 of the duct 1918 (e.g., a duct inlet, etc.) and the conduit outlet 1926 of the duct 1918 (e.g., a duct outlet, etc.). In some examples, exhaust flow enters the duct 1918 via the conduit inlet 1924 (e.g., from a chassis, etc.), through the flow conduit 1919, and into the first heat exchanger 1814 via the conduit outlet 1926. In the illustrated example of FIG. 19, the conduit inlet 1924 is larger than the conduit outlet 1926 due to the geometries of the first side wall 1920A and the second side wall 1920B. In the illustrated example of FIG. 19, the first side wall 1920A is generally planar (e.g., flat, straight, etc.) and the second side wall 1920B includes an example corner 1932, which reduces the flow area of the flow conduit 1919. In the illustrated example, the relationship of the side wall 1920A, 1920B causes the conduit outlet 1926 to have a smaller area than the conduit inlet 1924 (e.g., the conduit outlet 1926 defines a plane with a smaller area than a plane defined by the conduit inlet 1924, etc.). In other examples, the side walls 1920A, 1920B can have any other suitable geometry (e.g., the corner 1932 can be absent, the first side wall 1920A can include a corner similar to the corner 1932, etc.). In the illustrated example of FIG. 19, the side walls 1920A, 1920B have a same thickness. In other examples, the first side wall 1920A and the side wall 1920B can have different thicknesses.

In some examples, the geometry (e.g., the size, the shape, etc.) of the conduit inlet 1924 is based on the geometry of a chassis associated with the heat exchanger assembly 1900 (e.g., the chassis 1800 of FIG. 18, etc.). In some examples, the geometry (e.g., the size, the shape, etc.) of the conduit outlet 1926 is based on the geometry of the first heat exchanger 1814. In other examples, the geometries of the conduit outlet 1926 and/or the conduit inlet 1924 can be based on any other suitable considerations.

In the illustrated example of FIG. 19, the plates 1922A, 1922B extend away from the conduit outlet 1926 and the flow conduit 1919 and enable the duct to be coupled to the first heat exchanger 1814. In the illustrated example of FIG. 19, the first plate 1922A and the second plate 1922B have a same size, thickness, and shape. In other examples, the first plate 1922A and the second plate 1922B can have different sizes, thicknesses, and/or shapes. In the illustrated example of FIG. 19, the plates 1922A, 1922B have a same thickness as the side walls 1920A, 1920B. In other examples, the plates 1922A, 1922B can have different thicknesses from the first side wall 1920A and/or the second side wall 1920B. In some examples, one or both of the plates 1922A, 1922B can be absent. In some such examples, the duct 1918 and the first heat exchanger 1814 can be assembled and/or coupled via any suitable combination of fasteners, press fits, interference fits, chemical adhesives, and/or welds. In other examples, the duct 1918 and the first heat exchanger 1814 are integral components.

In the illustrated example of FIG. 19, the plates 1922A, 1922B of the duct 1918 abut the mounting surfaces 1912A, 1912B, respectively, such that the conduit outlet 1926 of the flow conduit 1919 is adjacent to the air flow inlet 1915A of the first heat exchanger 1814. In the illustrated example of FIG. 19, the rails 1908A, 1908B and the mounting surfaces 1912A, 1912B define respective channels for the plates 1922A, 1922B. In some such examples, the rails 1908A, 1908B of the first heat exchanger 1814 facilitate the alignment of the duct 1918 and the first heat exchanger 1814 during the assembly of the heat exchanger assembly 1900.

In the illustrated example of FIG. 19, the fasteners 1930A, 1930B, 1930C, 1930D, 1930E, 1930F couple the first heat exchanger 1814 to the duct 1918. For example, the first fastener 1930A is inserted through the first hole 1928A of the duct 1918 and is received by the first opening 1914A of the first heat exchanger 1814, the second fastener 1930B is inserted through the second hole 1928B of the duct 1918 and is received by the second opening 1914B of the first heat exchanger 1814, and the third fastener 1930C is inserted through the third hole 1928C of the duct 1918 and is received by the third opening 1914C of the first heat exchanger 1814. Similarly, the fourth fastener 1930D, the fifth fastener 1930E, and the sixth fastener 1930F can be inserted through the fourth hole 1928D, the fifth hole 1928E, and the sixth hole 1928F, respectively, and can be received by corresponding openings in the bottom of the first heat exchanger 1814 (not illustrated in FIG. 19).

In the illustrated example of FIG. 19, the fasteners 1930A, 1930B, 1930C, 1930D, 1930E, 1930F are screws configured to be received via threading of the openings of the first heat exchanger 1814 (e.g., the openings 1914A, 1914B, 1914C, etc.). In other examples, the fasteners 1930A, 1930B, 1930C, 1930D, 1930E, 1930F can be implemented by any other suitable type of fastener (e.g., bolts, rivets, etc.). In other examples, the openings are not threaded and/or tapped. In some such examples, the interior of the first heat exchanger 1814 can include one or more nuts to receive corresponding threads of the fasteners 1930A, 1930B, 1930C, 1930D, 1930E, 1930F. In the illustrated example, six fasteners (e.g., the fasteners 1930A, 1930B, 1930C, 1930D, 1930E, 1930F, etc.) are used to couple the first heat exchanger 1814 to the duct 1918. In other examples, different quantities of fasteners are used to couple the first heat exchanger 1814 to the duct 1918 (e.g., one fastener, two fasteners, four fasteners, seven fasteners, ten fasteners, etc.).

In the illustrated example of FIG. 19, the first hole 1928A, the second hole 1928B, and the third hole 1928C are formed in the first plate 1922A and the fourth hole 1928D, the fifth hole 1928E, and the sixth hole 1928F are formed in the second plate 1922B. In the illustrated example of FIG. 19, the holes 1928A, 1928B, 1928C, 1928D, 1928E, 1928F are through holes with counter sinks to ensure the heads of the fasteners 1930A, 1930B, 1930C, 1930D, 1930E, 1930F are flush with the top surfaces of the corresponding ones of the plates 1922A, 1922B. In other examples, the holes 1928A, 1928B, 1928C, 1928D, 1928E, 1928F can have any other suitable shape (e.g., counter bores, chamfers, etc.). In the illustrated example of FIG. 19, the first hole 1928A is axially aligned with the fourth hole 1928D, the second hole 1928B is axially aligned with the fifth hole 1928E, and the third hole 1928C is axially aligned with the sixth hole 1928F. In other examples, the holes 1928A, 1928B, 1928C, 1928D, 1928E, 1928F can have any other suitable configuration and/or spatial relationship.

Additionally or alternatively, the duct 1918 and the first heat exchanger 1814 can be coupled together via one or more welds between the plates 1922A, 1922B and the mounting surfaces 1912A, 1912B, one or more chemical adhesives between the plates 1922A, 1922B and the mounting surfaces 1912A, 1912B, one or more additional fasteners, one or more press fits, one or more shrink fits, etc. In some such examples, some or all the holes 1928A, 1928B, 1928C, 1928D, 1928E, 1928F, the fasteners 1930A, 1930B, 1930C, 1930D, 1930E, 1930F, and/or the openings 1914A, 1914B, 1914C are absent.

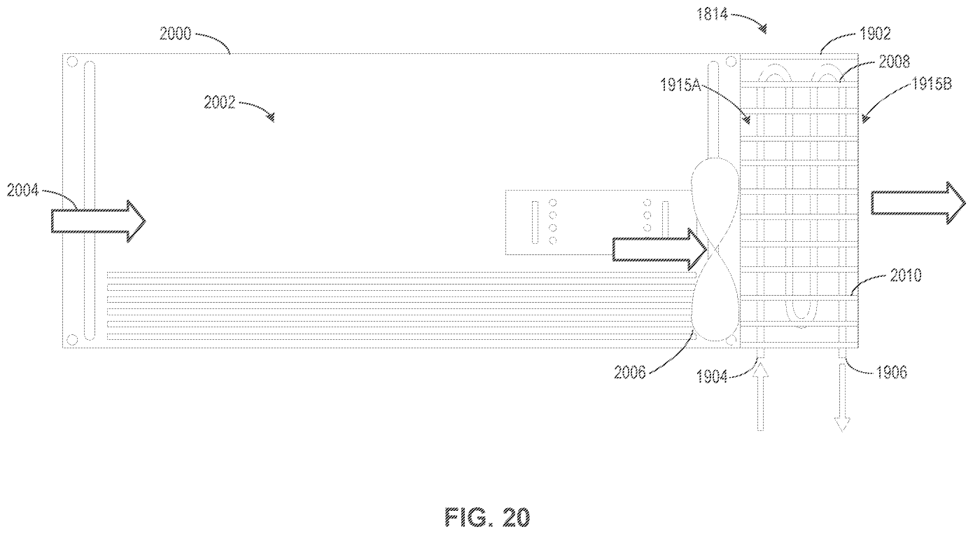

FIG. 20 is a schematic diagram of a fluid flow path through an example power supply assembly 2000 and the example first heat exchanger 1814 of FIGS. 18 and 19. In the illustrated example of FIG. 20, the example power supply assembly 2000 includes an example first internal flow path 2002 through which an example exhaust flow 2004 flows during the operation of the power supply assembly 2000. In the illustrated example of FIG. 20, the power supply assembly 2000 includes an example fan 2006. In the illustrated example of FIG. 20, the first heat exchanger 1814 includes an example internal coolant pathway 2008 and example fins 2010.

The fan 2006 is an electrically powered fan that causes the exhaust flow 2004 to flow through the internal flow path 2002 of the power supply assembly 2000 and into the first heat exchanger 1814. As the fan 2006 drives the exhaust flow through the internal flow path 2002 of the power supply assembly 2000, the exhaust flow 2004 increases in temperature as it draws heat from the power supply assembly 2000, thereby decreasing the temperature of the power supply assembly 2000. In some examples, the speed of the fan 2006 can be controlled to modify the velocity of the exhaust flow 2004, which changes the rate of heat transfer between (1) the exhaust flow 2004 and the power supply assembly 2000 and (2) the rate of heat transfer between the exhaust flow 2004 and the first heat exchanger 1814. In some such examples, the speed of the fan 2006 can be controlled via a controller of the first heat exchanger 1814 (e.g., the cooling system controller circuitry 2602 of FIG. 26, etc.). In the illustrated example of FIG. 20, the fan 2006 is an axial fan. In other examples, the fan 2006 can be a centrifugal fan. In the illustrated example of FIG. 20, the power supply includes a single fan (e.g., the fan 2006, etc.). In other examples, the power supply assembly 2000 can include a different number of fans (e.g., two fans, three fans, etc.). In some such examples, the power supply assembly 2000 can include no fans and the exhaust flow 2004 can be driven via an externally mounted fan (e.g., a fan associated with the first heat exchanger, etc.), one or more other fan coupled to a chassis housing the power supply assembly 2000, and/or natural convection.

The internal coolant pathway 2008 is a fluid flow path that extends between the heat exchanger coolant inlet 1904 of FIG. 19 and the heat exchanger coolant outlet 1906 of FIG. 19. As liquid coolant flows through the internal coolant pathway 2008, the exhaust flow 2004 and the body of the first heat exchanger 1814 are cooled via heat transfer (e.g., convection, etc.), thereby decreasing the temperature of the first heat exchanger 1814 and the exhaust flow 2004 and increasing the temperature of the liquid coolant in the internal coolant pathway 2008. In the illustrated example of FIG. 20, the internal coolant pathway 2008 is composed of a single continuous tube (e.g., pipe, etc.) of constant diameter that extends between the heat exchanger coolant inlet 1904 and heat exchanger coolant outlet 1906. In other examples, the internal coolant pathway can have any other suitable size and/or shape (e.g., prismatic, etc.) In other examples, the internal coolant pathway 2008 can include one or more branching pathways between the heat exchanger coolant inlet 1904 and the heat exchanger coolant outlet 1906. In some examples, the diameter of the internal coolant pathway 2008 can vary along the length of the internal coolant pathway 2008. In some examples, the internal coolant pathway 2008 can be composed of a material with comparatively high thermal conductivity (e.g., copper, aluminum, silver, silicon nitride, etc.). In other examples, the internal coolant pathway 2008 can be composed of any other suitable material. In some examples, the body 1902 of the first heat exchanger 1814 can include one or more baffles to support the internal coolant pathway 2008.

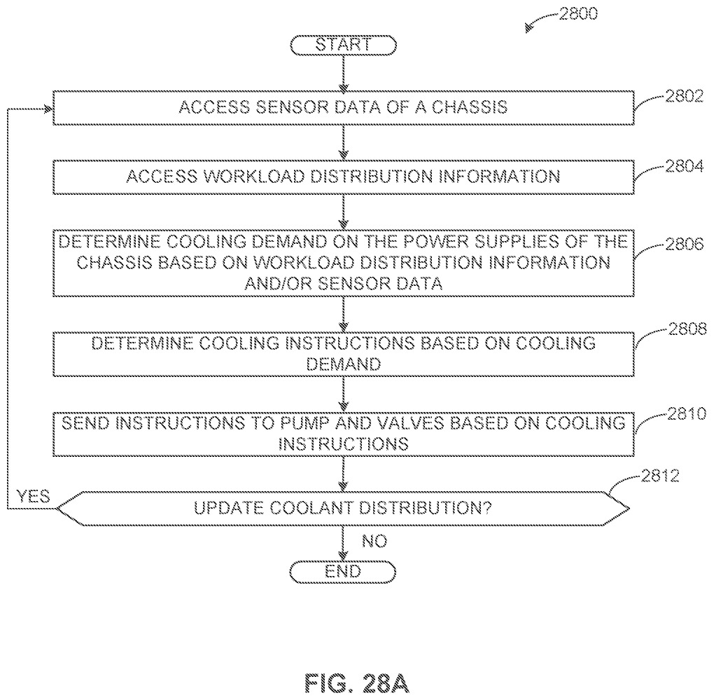

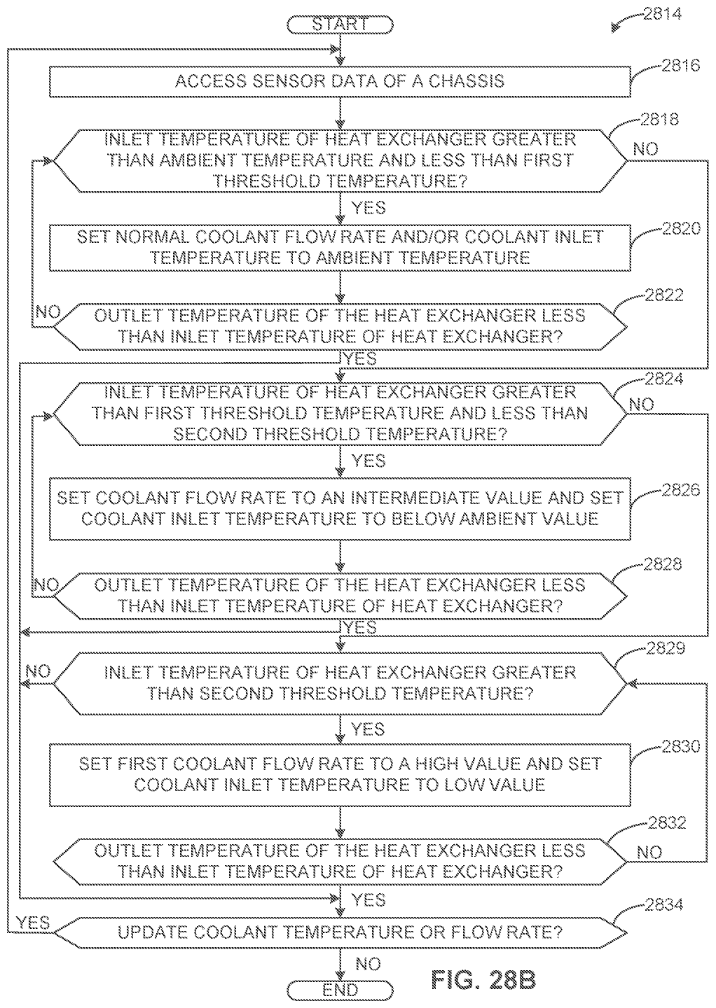

In some examples, the velocity of flow within the internal coolant pathway 2008 can be controlled to change the rate of heat transfer (e.g., convection, etc.) between the exhaust flow 2004 and the first heat exchanger 1814 and/or the liquid coolant within the internal coolant pathway 2008. An example controller to control the velocity of coolant through the internal coolant pathway 2008 is described below in conjunction with FIGS. 26 and 27. Example operations to control the velocity of coolant through the internal coolant pathway 2008 are described below in conjunction with FIGS. 28A and 28B.

In the illustrated example of FIG. 20, the first heat exchanger 1814 is a shell-and-tube heat exchanger (e.g., the internal coolant pathway 2008 acts as the tube, and the flow path of the body 1902 acts as the shell, etc.). In other examples, the first heat exchanger 1814 can be implemented by a double-pipe heat exchanger, a plate heat exchanger, a spiral heat exchanger, a helical coil heat exchanger, etc. In the illustrated example of FIG. 20, the first heat exchanger 1814 has a cross-flow configuration (e.g., the internal coolant pathway 2008 is generally perpendicular to the flow of the exhaust flow 2004, etc.). In other examples, the first heat exchanger 1814 can have a parallel flow and/or a cross-flow configuration. While the internal coolant pathway 2008 is depicted as including three 180-degree curves in the illustrated example of FIG. 20, such geometry is included for illustrative purposes in the 2-dimensional schematic diagram of FIG. 20. In other examples, the internal coolant pathway 2008 can have any other suitable geometry for the three-dimensional space of the body 1902 of the first heat exchanger 1814. For example, the internal coolant pathway 2008 can include any suitable combinations of curves and/or bends in a three-dimensional space.

The fins 2010 are a plurality of internal structures within the body 1902 that increase the surface area of the body 1902 of the first heat exchanger 1814 exposed to the exhaust flow 2004. The fins 2010 increase the rate of heat transfer (e.g., convection, etc.) between the exhaust flow and the body 1902 of the first heat exchanger 1814. In some examples, the fins 2010 and/or other structures within the body 1902 can be configured to increase the turbulence of the exhaust flow 2004, which increases the rate of heat transfer (e.g., convection, etc.) between the exhaust flow 2004 and the body 1902 of the first heat exchanger 1814. Additionally or alternatively, the body 1902 of the first heat exchanger 1814 can include any other suitable structure(s) (e.g., channels, bosses, etc.) with a comparatively high surface area to increase the rate of convection between the exhaust flow 2004 and the first heat exchanger 1814 and/or the internal coolant pathway 2008. The fins 2010 can include one or more openings to enable the internal coolant pathway 2008 to extend therethrough.

In some examples, the fins 2010 can be formed during the forming of the other components of the first heat exchanger 1814 (e.g., via additive manufacturing, via casting, via machining, etc.). In some such examples, the fins 2010 can be composed of a same material as the body 1902 of the first heat exchanger 1814. In some examples, the fins 2010 can be manufactured separately and coupled within the body 1902 via one or more fasteners, one or more welds, one or more press fits, one or more shrink fits, one or more chemical adhesives, etc.). In some such examples, the fins 2010 can be composed of the same material as the body 1902 and/or different material with comparatively high thermal conductivity (e.g., copper, aluminum, sliver, silicon nitride, etc.). In some such examples, the body 1902 can include features (e.g., slots, holes, weld surfaces, etc.) that facilitate the coupling of the fins 2010 thereto.

In the illustrated example of FIG. 20, the fins 2010 extend parallel to the flow of the exhaust flow 2004 between the air flow inlet 1915A and the air flow outlet 1915B. In other examples, the fins 2010 can have a different configuration (e.g., portions perpendicular to the flow of the exhaust flow 2004, etc.) and/or can be disposed downstream of the air flow inlet 1915A. In other examples, the fins 2010 are absent. In the illustrated example of FIG. 20, the fins 2010 are evenly distributed along the height of the first heat exchanger 1814. In other examples, the fins 2010 can have any other suitable distribution. In the illustrated example of FIG. 20, there is not a duct disposed between the power supply assembly 2000 and the first heat exchanger 1814. In other examples, a duct (e.g., the duct 1918 of FIG. 19, etc.) can be disposed in the flow path of the exhaust flow 2004 to guide the exhaust flow 2004 between the power supply and the first heat exchanger 1814.

FIG. 21-23 are perspective views depicting an example process of coupling the first heat exchanger 1814 to the chassis 1800. While FIGS. 21-23 depict one such process of coupling the first heat exchanger 1814 to the chassis 1800, it should be appreciated that the first heat exchanger 1814 and the chassis 1800 can be assembled in any other suitable manner.

FIG. 21 is a perspective view of the chassis 1800 of FIG. 18 in an example first state 2100. In the illustrated example of FIG. 21, an example holder assembly 2102 is disposed within the example first slot 1808A of FIG. 18. In the illustrated example of FIG. 21, the holder assembly 2102 includes an example bracket 2104 that includes an example first mounting feature 2106A, an example second mounting feature 2106B, an example third mounting feature 2106C, and an example fourth mounting feature 2106D. In the illustrated example of FIG. 21, the holder assembly 2102 includes an example handle 2108 and an example holder frame 2110.

In the illustrated example of FIG. 21, the holder assembly 2102 is shaped to fit within (e.g., be disposed within, etc.) one or more of the slots of the chassis 1800 (e.g., the first slot 1808A, the second slot 1808B, etc.). In other examples, the holder assembly 2102 can have any other suitable shape. The holder assembly 2102 is configured to house a power supply (e.g., the power supply assembly 2000 of FIG. 20, etc.) of the chassis 1800. In the illustrated example of FIG. 21, the holder assembly 2102 includes the holder frame 2110. The holder frame 2110 is a structure configured to hold a power supply and couple the power supply within a slot of the chassis 1800 (e.g., the first slot 1808A, the second slot 1808B, etc.). In some examples, the holder frame 2110 can include one or more feature(s) that enable the holder frame 2110 to be disposed within the chassis 1800. For example, the holder frame 2110 can include one or more rails, one or more slots, one or more fasteners, one or more holes, etc. that facilitate the coupling of the holder frame 2110 within the slots 1808A, 1808B, etc. In some examples, the holder frame 2110 can include one or more feature(s) that enable a power supply to be disposed therein. For example, the holder frame 2110 can include one or more rails, one or more slots, one or more fasteners, one or more holes, etc. that facilitate the coupling of a power supply within the holder frame 2110. The holder frame 2110 can be composed of one or more metals (e.g., aluminum, steel, copper, etc.), one or more polymers (e.g., a thermoset plastic, a thermoplastic, etc.), one or more ceramics, and/or a combination thereof. In some examples, the holder frame 2110 can include one or more electrical interfaces (not illustrated) that enable power to be transferred to a power supply disposed therein (e.g., an alternating current input, etc.) and/or from a power supply disposed therein (e.g., a direct current output, etc.). In some examples, the holder frame 2110 can include one or more data interfaces (not illustrated) that permit information to be transferred between a power supply disposed therein and other components of the chassis 1800 and/or an external controller (e.g., the cooling system controller circuitry 2602 of FIG. 26, etc.). In some examples, the holder frame 2110 can include one or more sensors that measure the flow rate of exhaust through a power supply disposed therein, a temperature of the exhaust flow through a power supply disposed therein, etc.

In the illustrated example of FIG. 21, the holder assembly 2102 includes a bracket 2104 coupled to the holder frame 2110 in a position distal to the chassis 1800. In the illustrated example of FIG. 21, the bracket 2104 protrudes from the rear 1809 of the chassis 1800 and the holder frame 2110 is disposed within the chassis 1800. In the illustrated example of FIG. 21, the bracket 2104 is integral with a bottom surface of the holder frame 2110. In some examples, the bracket 2104 can be composed of the same material as the holder frame 2110. In other examples, the bracket 2104 can be a separate component from the holder frame 2110. For example, the bracket 2104 can be manufactured separately from the holder frame 2110 and coupled thereto via one or more fasteners, one or more chemical adhesives, one or more welds, one or more press fits, etc. The bracket 2104 can be composed of any suitable material including a metal, a polymer, a ceramic, and/or a combination thereto.

In the illustrated example of FIG. 21, the bracket 2104 includes the mounting features 2106A, 2106B, 2106C, 2106D, and defines the channel 2107. In the illustrated example of FIG. 21, the channel 2107 has a size and shape that facilitates the deposition of a power supply within the holder frame 2110 (e.g., sized to enable a power supply to slide therethrough, etc.). In other examples, the channel 2107 can have any other suitable shape.

The mounting features 2106A, 2106B, 2106C, 2106D facilitate the coupling of a heat exchanger within the channel 2107 of the bracket 2104, to the holder assembly 2102, and to the chassis 1800. In the illustrated example of FIG. 21, the mounting features 2106A, 2106B, 2106C, 2106D are slots formed within the bracket 2104. In the illustrated example of FIG. 21, the mounting features 2106A, 2106B, 2106C, 2106D are straight slots. In other examples, the mounting features 2106A, 2106B, 2106C, 2106D can be implemented by slots including one or more curves (e.g., L-shaped slots, C-shaped slots, etc.). In other examples, the mounting features 2106A, 2106B, 2106C, 2106D can be implemented by any other suitable features (e.g., holes, weld surfaces, spring pins, etc.). In the illustrated example of FIG. 21, the bracket 2104 includes four mounting features (e.g., the mounting features 2106A, 2106B, 2106C, 2106D, etc.). In other examples, the bracket 2104 can include any other suitable number of mounting features (e.g., one mounting feature, two mounting features, five mounting features, etc.).

The handle 2108 is a mechanical structure that facilitates the handling of the holder assembly 2102. For example, the handle 2108 facilitates the coupling of the holder assembly 2102 within the first slot 1808A and/or removal therefrom. In the illustrated example of FIG. 21, the handle 2108 is a U-shaped member that is coupled to the holder frame 2110 at two locations. In other examples, the handle 2108 can have any other suitable shape and can be coupled to the holder assembly 2102 at any other suitable location. In some examples, the handle 2108 can be absent. In some such examples, the holder assembly 2102 can include other features that facilitate the handling, assembly, and/or removal of the holder assembly 2102.

In the illustrated example of FIG. 21, the holder assembly 2102 can be coupled within the first slot 1808A via an example translation 2112. In some such examples, the holder assembly 2102 can be retained within the first slot 1808A via one or more fasteners and/or locking mechanisms between the holder assembly 2102 and a feature of the chassis 1800 proximate to the first slot 1808A. In some examples, a holder assembly similar to the holder assembly 2102 can be deposed within the second slot 1808B to enable the coupling of a heat exchanger thereto.

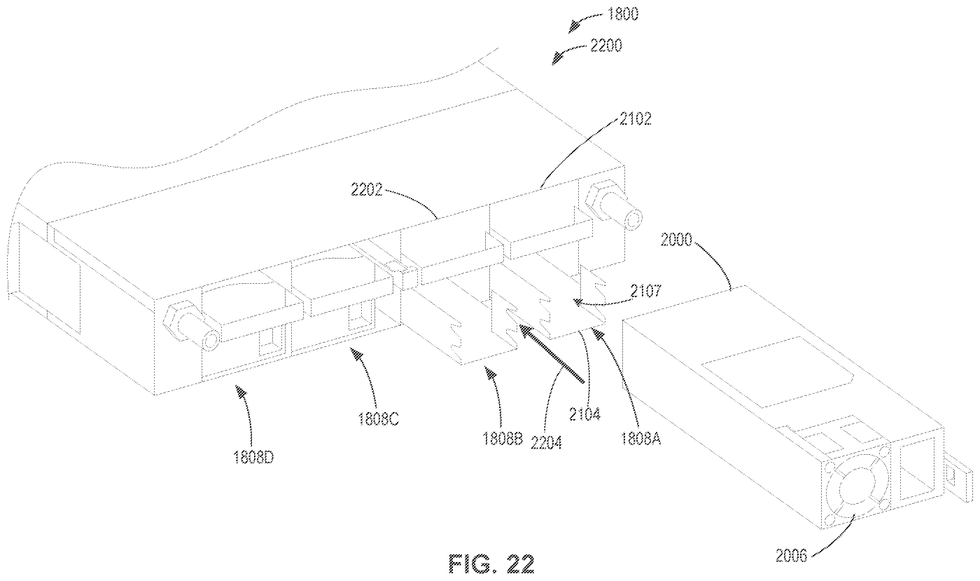

FIG. 22 is a perspective view of the chassis 1800 of FIG. 18 in an example second state 2200 following the first state 2100 of FIG. 21. In the illustrated example of FIG. 22, the holder assembly 2102 is disposed in the first slot 1808A and another example holder assembly 2202 similar to the holder assembly 2102 has been disposed in the second slot 1808B. In some examples, holder assemblies similar to the holder assemblies 2102, 2202 can be disposed within the third slot 1808C and/or the fourth slot 1808D. In the illustrated example of FIG. 22, the power supply assembly 2000 of FIG. 20 is to be disposed within the holder assembly 2102. In the illustrated example of FIG. 22, the fan 2006 is aligned with the channel 2107 of the holder assembly 2102 such that exhaust air from the power supply assembly 2000 is to flow through the channel 2107.

In the illustrated example of FIG. 22, the power supply assembly 2000 can be coupled within the holder assembly 2102 via an example translation 2204. In some such examples, the power supply assembly 2000 can be retained within the holder assembly 2102 and/or the first slot 1808A via one or more fasteners and/or locking mechanisms between the holder assembly 2102 and a feature of the chassis 1800 proximate to the first slot 1808A.

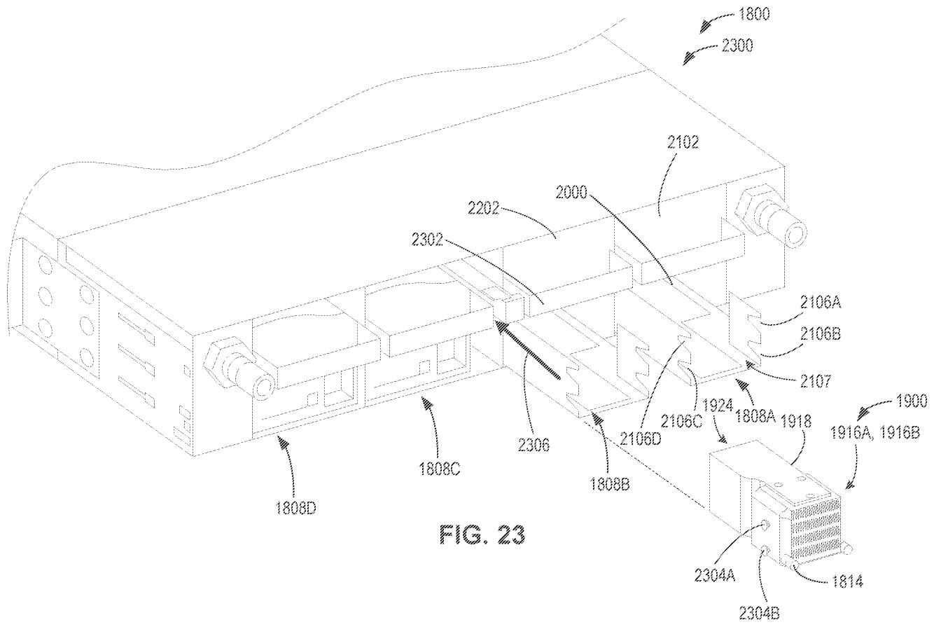

FIG. 23 is a perspective view of the chassis 1800 of FIG. 18 in an example third state 2300 following the second state 2200 of FIG. 22. In the illustrated example of FIG. 23, the power supply assembly 2000 has been disposed within the holder assembly 2102 in the first slot 1808A and another power supply assembly 2302, similar to the power supply assembly 2000, has been disposed within the holder assembly 2202 in the second slot 1808B. In some examples, power supplies similar to the power supply assemblies 2000, 2302 can be disposed within the third slot 1808C and/or the fourth slot 1808D. In the illustrated example of FIG. 23, the heat exchanger assembly 1900 of FIG. 19 is to be disposed within the holder assembly 2102 in the first slot 1808A. In the illustrated example of FIG. 23, the heat exchanger assembly 1900 includes the first bracket fastener 1916A of FIG. 19, the second bracket fastener 1916B of FIG. 19, an example third bracket fastener 2304A, and an example fourth bracket fastener 2304B.

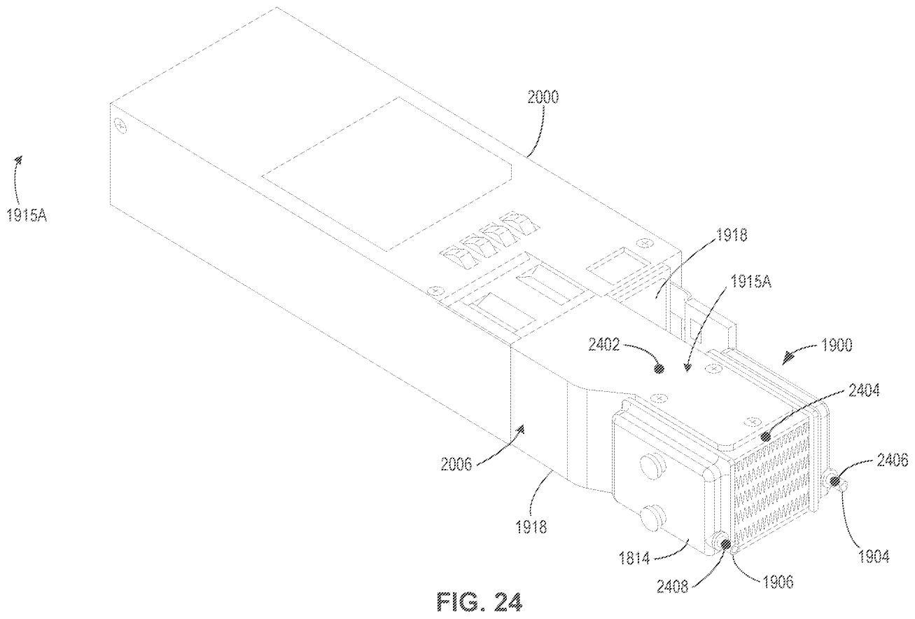

To couple the heat exchanger assembly 1900 to the holder assembly 2102 and the chassis 1800, the heat exchanger assembly 1900 can be moved into the channel 2107 of the bracket 2104 via an example translation 2306. In the illustrated example of FIG. 23, the translation 2306 causes the bracket fasteners 1916A, 1916B, 2304A, 2304B to be aligned with the mounting features 2106A, 2106B, 2106C, 2106D, respectively. In the illustrated example of FIG. 23, to fasten the heat exchanger assembly 1900 to the holder assembly 2102, the brackets fasteners 1916A, 1916B, 2304A, 2304B can be tightened, which retains the heat exchanger assembly 1900 in the channel 2107 via a frictional interface between the first bracket fastener 1916A and the first mounting feature 2106A, a frictional interface between the second bracket fastener 1916B and the second mounting feature 2106B, a frictional interface between the third bracket fastener 2304A and the third mounting feature 2106C, and a frictional interface between the fourth bracket fastener 2304B and the fourth mounting feature 2106D. The relationship between the heat exchanger assembly 1900 and the power supply assembly 2000 is described in further detail below in conjunction with FIG. 24.

FIG. 24 is a perspective view of the first heat exchanger 1814 of FIGS. 18-23 coupled to the power supply assembly 2000 of FIGS. 20 and 22 following the third state 2300 of FIG. 23. In the illustrated example of FIG. 24, the coupling between the heat exchanger assembly 1900 to the holder assembly 2102 of FIG. 21 (e.g., via the bracket fasteners 1916A, 1916B, 2304A, 2304B and the mounting features 2106A, 2106B, 2106C, 2106D, etc.) causes the duct 1918 to abut the power supply assembly 2000 such that the conduit inlet 1924 is proximate to the fan 2006 of the power supply assembly 2000. In the illustrated example of FIG. 24, the conduit inlet 1924 encompasses the fan 2006, and the fan 2006 and the conduit inlet 1924 have substantially the same area. In other examples, the conduit inlet 1924 and the fan 2006 can have other suitable relationship(s). For example, the conduit inlet 1924 can be substantially larger than the fan 2006 (e.g., extend along an entire length of the power supply assembly 2000, etc.).

In the illustrated example of FIG. 24, the first heat exchanger 1814 includes an example first sensor 2402, an example second sensor 2404, an example third sensor 2406, and an example fourth sensor 2408. In the illustrated example of FIG. 24, the first sensor 2402 and the second sensor 2404 measure the temperature of the air at the air flow inlet 1915A and the temperature of the air at the air flow outlet 1915B, respectively. In the illustrated example of FIG. 24, the third sensor 2406 and the fourth sensor 2408 measure the temperature of the liquid coolant at the coolant inlet 1904 and the temperature of the liquid coolant at the coolant outlet 1906.

In the illustrated example of FIG. 24, the first sensor 2402 is disposed adjacent to the air flow inlet 1915A. In other examples, the first sensor 2402 can be disposed at another location within the duct 1918 and/or near the fan 2006. In the illustrated example of FIG. 24, the third sensor 2406 and the fourth sensor 2408 are disposed within the coolant inlet 1904 and the coolant outlet 1906, respectively. In other examples, the third sensor 2406 can be disposed at another location upstream in the coolant system (e.g., in the inlet coolant manifold 2604 of FIG. 26, in an outlet of a coolant distribution unit, etc.) and/or the fourth sensor 2408 can be disposed at another location downstream in the coolant system (e.g., the outlet coolant manifold 2606 of FIG. 26, in an inlet of a coolant distribution unit, etc.). One or more of the sensors 2402, 2404, 2406, 2408 can be implemented by one or more thermocouple(s), one or more resistance temperature detector(s), one or more thermistor(s), one or more infrared optical sensor(s), one or more semiconductor-based sensors, and/or a combination thereof.

FIG. 25 is a perspective view of another example chassis 2500 including another example heat exchanger assembly 2502 implemented in accordance with the teachings of this disclosure. The chassis 2500 of FIG. 25 is similar to the chassis 1800 of FIG. 18, except that the chassis 2500 includes an example heat exchanger assembly 2502. In the illustrated example of FIG. 25, the heat exchanger assembly 2502 includes an example heat exchanger 2504, an example first duct 2506A, an example second duct 2506B, an example third duct 2506C, and an example fourth duct 2506D. In the illustrated example of FIG. 25, the ducts 2506A, 2506B, 2506C, 2506D are disposed within an example first slot 2508A, an example second slot 2508B, an example third slot 2508C, and an example fourth slot 2508D, respectively. In the illustrated example of FIG. 25, the heat exchanger 2504 includes an example body 2510, an example air flow outlet 2512, an example first side portion 2514A, an example second side portion 2514B, an example liquid coolant inlet 2518, an example liquid coolant outlet 2520, an example first bracket fastener 2522A, and an example second bracket fastener 2522B. In the illustrated example of FIG. 25, the chassis 2500 includes an example chassis coolant inlet 2523 and an example chassis coolant outlet 2524 disposed on an example rear 2526 of the chassis 2500.

The heat exchanger 2504 is an air-to-liquid heat exchanger that cools exhaust air flow from the rear of the chassis 2500. In the illustrated example of FIG. 25, the heat exchanger 2504 is a shell-and-tube heat exchanger similar to the first heat exchanger 1814 of FIGS. 18-24, except the heat exchanger 2504 receives exhaust air flow from each of the slots 2508A, 2508B, 2508C, 2508D. In other examples, the heat exchanger 2504 is implemented by a double-pipe heat exchanger, a plate heat exchanger, a spiral heat exchanger, a helical coil heat exchanger, etc. In some examples, the heat exchanger 2504 can cool exhaust flows from four power supplies (e.g., power supplies, etc.) associated with each of the slots 2508A, 2508B, 2508C, 2508D.

In some examples, the interior of the body 2510 of the heat exchanger 2504 can include structures that increase the surface area of the body 2510 of the heat exchanger 2504 (e.g., fins similar to the fins 2010 of FIG. 20, channels, bosses, etc.). In some such examples, the internal structures of the heat exchanger 2504 increase the rate of heat transfer (e.g., convection, etc.) between the heat exchanger 2504 and the exhaust flow. In some examples, the internal structures of the body 2510 can be evenly distributed throughout the body 2510. In other examples, the internal structures can have suitable distribution in the body 2510. In some examples, the body 2510 does not include such surface area-increasing structures.

The heat exchanger 2504 includes an internal coolant pathway between the liquid coolant inlet 2518 and the liquid coolant outlet 2520 that cools the heat exchanger 2504 and the exhaust flow from the chassis 2500 flowing therethrough. The internal coolant pathway of the heat exchanger 2504 can have any suitable configuration (e.g., a cross-flow configuration, a parallel flow, and a counter flow configuration, etc.). In some examples, the internal coolant pathway can be a single continuous conduit (e.g., tube, pipe, etc.) between the liquid coolant inlet 2518 and the liquid coolant outlet 2520. In other examples, the internal coolant pathway can include one or more branching conduits between the liquid coolant inlet 2518 and the liquid coolant outlet 2520. In some such examples, the branching of the liquid coolant inlet 2518 and the liquid coolant outlet 2520 facilitates substantially equal outlet flow along the length of the heat exchanger 2504 and an even distribution of fresh liquid coolant (e.g., comparatively cool liquid coolant, etc.).

The liquid coolant inlet 2518 and the liquid coolant outlet 2520 are ports that permit liquid coolant to enter and leave the internal flow path of the heat exchanger 2504. In the illustrated example of FIG. 25, the liquid coolant inlet 2518 and the liquid coolant outlet 2520 are disposed on the first side portion 2514A and the second side portion 2514B, respectively, and are adjacent to the air flow outlet 2512. In the illustrated example of FIG. 25, the liquid coolant inlet 2518 is proximate to the first slot 2508A and the liquid coolant outlet 2520 is proximate to the second slot 2508B. In the illustrated example of FIG. 25, the liquid coolant inlet 2518 and the liquid coolant outlet 2520 are disposed on the same side of the body 2510 (e.g., a rear side of the body 2510, etc.) and are substantially the same height relative to the body 2510. In other examples, the liquid coolant inlet 2518 and the liquid coolant outlet 2520 can be disposed at any other suitable locations (e.g., other location(s) on the side portions 2514A, 2514B, on a side of the body 2510, on a rear of the body 2510, etc.). In some examples, during the operation of the heat exchanger 2504, the coolant enters the heat exchanger 2504 via the liquid coolant inlet 2518 and leaves the heat exchanger 2504 via the liquid coolant outlet 2520 at a constant and equal or substantially constant and equal rate.

In some examples, the velocity of liquid coolant flow within the internal flow path of the heat exchanger 2504 can be controlled to change the rate of heat transfer (e.g., convection, etc.) between the exhaust flow of the chassis 2500 and the heat exchanger 2504 and/or the coolant within the liquid coolant within the internal flow path of the heat exchanger 2504. In some examples, the flow rate of the liquid coolant in the heat exchanger 2504 can be controlled to make the flow exiting from the heat exchanger 2504 via the air flow outlet 2512 substantially equal in temperature to the ambient environment of the heat exchanger 2504 and/or chassis 2500. Example controller circuitry to control the velocity of coolant through the heat exchanger 2504 is described below in conjunction with FIGS. 26 and 27. Example operations to control the velocity of coolant through the heat exchanger 2504 are described below in conjunction with FIGS. 28A and 28B.

In the illustrated example of FIG. 25, the heat exchanger 2504 receives exhaust air from each of the slots 2508A, 2508B, 2508C, 2508D via the ducts 2506A, 2506B, 2506C, 2506D. The ducts 2506A, 2506B, 2506C, 2506D guide the exhaust flow from each of the slots 2508A, 2508B, 2508C, 2508D to the heat exchanger 2504. Each of the ducts 2506A, 2506B, 2506C, 2506D is similar to the duct 1918 of FIG. 19, except that the ducts 2506A, 2506B, 2506C, 2506D of FIG. 25 channel exhaust air from the chassis 2500 to a single heat exchanger, the heat exchanger 2504. In some examples, the heat exchanger 2504 includes air flow inlets adjacent to each of the ducts 2506A, 2506B, 2506C, 2506D. The ducts 2506A, 2506B, 2506C, 2506D can be coupled to the heat exchanger 2504 in a manner similar to the fastening of the duct 1918 of FIG. 19 to the first heat exchanger 1814 (e.g., via a plurality of screws extending through holes on the tops and bottoms of the ducts 2506A, 2506B, 2506C, 2506D, and into the heat exchanger 2504). In other examples, the ducts 2506A, 2506B, 2506C, 2506D can be coupled to the heat exchanger 2504 via one or more other fasteners, one or more welds, one or more chemical adhesives, one or more press fits, one or more shrink fits, and/or a combination thereof. Additionally or alternatively, one or more of the ducts 2506A, 2506B, 2506C, 2506D and the heat exchanger 2504 can be integral components.

The bracket fasteners 2522A, 2522B are fasteners disposed on the first side portion 2514A. In the illustrated example of FIG. 25, the bracket fasteners 2522A, 2522B are similar to the bracket fasteners 1916A, 1916B, 2304A, 2304B of FIG. 23. In some examples, the second side portion 2514B can include bracket fasteners similar to the bracket fasteners 2522A, 2522B of FIG. 25 and/or the bracket fasteners 1916A, 1916B, 2304A, 2304B of FIG. 23. In some examples, to couple the heat exchanger assembly 2502 to the chassis 2500, the bracket fasteners 2522A, 2522B can be aligned with corresponding mounting features (e.g., mounting features similar to mounting features 2106A, 2106B, 2106C, 2106D, of FIG. 24, etc.) of a bracket (e.g., a bracket similar to bracket 2104 of FIG. 24, etc.) associated with the fourth slot 2508D. In some such examples, bracket fasteners (not illustrated) associated with the second side portion 2514B can be aligned with corresponding mounting features associated with the first slot 2508A. In some examples, to fasten the heat exchanger assembly 2502 to the chassis 2500, the bracket fasteners 2522A, 2522B, and the bracket fasteners disposed on the second side portion 2514B can be tightened, which forms frictional interfaces between such bracket fasteners and corresponding mounting features of the chassis 2500. Additionally or alternatively, the heat exchanger assembly 2502 can be coupled to the chassis 2500 via one or more other fasteners, one or more welds, one or more chemical adhesives, one or more press fits, one or more shrink fits, and/or a combination thereof.

The chassis coolant inlet 2523 and the chassis coolant outlet 2524 are ports that permit liquid coolant to enter and leave a cooling system (not illustrated) of the chassis 2500. In the illustrated example of FIG. 25, the chassis coolant inlet 2523 and the chassis coolant outlet 2524 are disposed on opposite sides of the rear 2526 of the chassis 2500. In other examples, the chassis coolant inlet 2523 and the chassis coolant outlet 2524 can be disposed at any other suitable locations (e.g., another location on the rear 2526 of the chassis 2500, on a side of the chassis 2500, a front of the chassis 2500, etc.). In some examples, the chassis coolant inlet 2523 and the liquid coolant inlet 2518 can receive liquid coolant from the same source (e.g., a coolant distribution unit (CDU) associated with the chassis 2500, etc.). In some examples, the liquid coolant outlet 2520 and the chassis coolant outlet 2524 can expel liquid coolant to the same source (e.g., a coolant distribution unit (CDU) associated with the chassis 2500, etc.). In other examples, the coolant inlet 2523 and the chassis coolant outlet 2524 can be absent (e.g., if the chassis 2500 has an air cooling system, etc.).

In the illustrated example of FIG. 25, the chassis 2500 has an example chassis width 2528 and an example chassis height 2530. In the illustrated example of FIG. 25, the heat exchanger 2504 has an example heat exchanger width 2532 and an example heat exchanger height 2534. In the illustrated example of FIG. 25, the ratio of the chassis width 2528 and the heat exchanger width 2532 is approximately 1.48. In other examples, the ratio of the chassis width 2528 and the heat exchanger width 2532 can be any suitable value between 1 and 3. Additionally or alternatively, the heat exchanger width 2532 is based on the distance between the first slot 2508A and the fourth slot 2508D (e.g., the heat exchanger 2504 is long enough to receive exhaust flow from the first slot 2508A and the fourth slot 2508D, etc.). In the illustrated example of FIG. 25, the ratio of the chassis height 2530 and the heat exchanger height 2534 is approximately 2.25. In other examples, the ratio between the chassis height 2530 and the heat exchanger height 2534 can be any suitable value between 1 and 4.

The heat exchanger assembly 2502 described in conjunction with FIG. 25 cools the exhaust flow from four power supplies. It should be appreciated that teachings disclosed herein are also applicable to heat exchanger assemblies that service different numbers of slots. For example, the heat exchanger assemblies implemented in accordance with teachings of this disclosure and similar to the heat exchanger assembly 2502 can provide cooling to a chassis with any number of slots (e.g., two slots, three slots, five slots, ten slots, etc.). Additionally, two heat exchanger assemblies implemented in accordance with teachings of this disclosure and similar to the heat exchanger assembly of FIG. 25 could provide exhaust cooling to one or more chassis similar to the chassis 2500 of FIG. 25 (e.g., (1) a first heat exchanger assembly could cool the exhaust of the first slot 2508A and the second slot 2508B, and a second heat exchanger assembly could cool the exhaust of the third slot 2508C and the fourth slot 2508D, (2) a first heat exchanger assembly could cool the exhaust of the first slot 2508A, the second slot 2508B and a third slot 2508C, and a second heat exchanger assembly could cool the exhaust of the fourth slot 2508D, etc.).

FIG. 26 is a perspective view of a liquid coolant distribution system 2600 including the chassis 1800 and heat exchangers 1814, 1816 of FIG. 18 including example cooling system controller circuitry 2602. In the illustrated example of FIG. 26, the liquid coolant distribution system 2600 includes an example inlet coolant manifold 2604, an example outlet coolant manifold 2606, an example pump 2608, and example sensors 2610. In the illustrated example of FIG. 26, the example inlet coolant manifold 2604 is coupled an example main inlet line 2612, an example chassis inlet line 2614, an example first heat exchanger inlet line 2616, and an example second heat exchanger inlet line 2618 In the illustrated example of FIG. 26, the example inlet coolant manifold 2604 includes an example first valve 2620 and an example second valve 2622. In the illustrated example of FIG. 26, the example outlet coolant manifold 2606 is coupled to an example main outlet line 2624, an example chassis outlet line 2626, an example first heat exchanger outlet line 2628, and an example first heat exchanger outlet line 2630. In the illustrated example of FIG. 26, the example outlet coolant manifold 2606 includes an example third valve 2632 and an example fourth valve 2634. While the liquid coolant distribution system 2600 is described with reference to the chassis 1800 of FIG. 18 and heat exchangers 1814, 1816 of FIG. 18, the cooling system controller circuitry 2602, the manifolds 2604, 2606, the pump 2608, and the sensors 2610 can be used in conjunction with other systems, including the chassis 2500 and heat exchanger assembly 2502 of FIG. 25. In the illustrated example of FIG. 26, the manifolds 2604, 2606 include an example fifth valve 2636 and an example sixth valve 2638, which regulate the flow coolant from the chassis 1800.

The inlet coolant manifold 2604 is a mechanical structure that distributes fresh liquid coolant (e.g., cooled liquid coolant, new liquid coolant, etc.) between the cooling system of the chassis 1800 and the internal flow paths of the first heat exchanger 1814 and the second heat exchanger 1816. In the illustrated example of FIG. 26, the inlet coolant manifold 2604 includes the valves 2620, 2622, 2636 that control the flow rate of liquid coolant through the lines 2616, 2618, 2614, respectively. In the illustrated example of FIG. 26, the inlet coolant manifold 2604 is a free-standing structure separate from the chassis 1800. In other examples, the inlet coolant manifold 2604 can be coupled to the chassis 1800, to a server rack associated with the chassis 1800, a CDU associated with the server rack, etc. In some examples, the inlet coolant manifold 2604 can be absent. In some such examples, the function of the inlet coolant manifold 2604 can be implemented by one or more valves of a CDU.

The outlet coolant manifold 2606 is a mechanical structure that returns stale liquid coolant (e.g., heated liquid coolant, old liquid coolant, etc.) from the cooling system of the chassis 1800 and the internal flow paths of the first heat exchanger 1814 and the second heat exchanger 1816 to a CDU. In the illustrated example of FIG. 26, the outlet coolant manifold 2606 includes the valves 2632, 2634, 2638 that control the flow rate of liquid coolant through the lines 2626, 2628, 2630 respectively. In the illustrated example of FIG. 26, the inlet coolant manifold 2604 is a free-standing structure separate from the chassis 1800. In other examples, the inlet coolant manifold 2604 can be coupled to the chassis 1800, to a server rack associated with the chassis 1800, a CDU associated with the server rack, etc. Additionally or alternatively, the outlet coolant manifold 2606 can be integral with and/or coupled to the inlet coolant manifold 2604. In some examples, the outlet coolant manifold 2606 can be absent. In some such examples, the function of the outlet coolant manifold 2606 can be implemented by one or more valves of a CDU.

The pump 2608 pumps or drives the liquid coolant through the liquid coolant distribution system 2600. In some examples, the cooling system controller circuitry 2602 can control the power output of the pump 2608 to regulate the flow of coolant through the liquid coolant distribution system 2600. In the illustrated example of FIG. 26, the pump 2608 is external to the chassis 1800 and the heat exchangers 1814, 1816. In other examples, chassis 1800 and/or one or both of the heat exchangers 1814, 1816 can include an internal pump. In some such examples, the pump 2608 can be powered by a power supply of the chassis 1800 (e.g., the power supply assembly 2000 of FIG. 20, etc.). In other examples, the pump 2608 can be externally powered. In some examples, the pump 2608 is implemented by a centrifugal pump. In other examples, the pump 2608 can be implemented by one or more other suitable types of pumps (e.g., a positive-displacement pump, an axial-flow pump, an impulse pump, a rotodynamic pump, etc.) or a combination thereof. In some examples, the liquid coolant distribution system 2600 can include additional pumps.

The sensors 2610 measure and output signals corresponding to the liquid coolant distribution system 2600. For example, the sensors 2610 can include temperature sensors that measure the temperature of one or more compute units of the chassis 1800 (e.g., a temperature of one or more of the compute components 1804 of FIG. 18, etc.), a temperature of one or more power supplies associated with the power supplies of the chassis 1800 (e.g., the power supply assembly 2000 of FIG. 20, etc.), a temperature of exhaust air flow entering the heat exchangers 1814, 1816, a temperature of the coolant within one or more of the coolant lines 2614, 2616, 2618, 2626, 2628, 2630, etc. In some examples, the sensors 2610 can include one or more thermocouple(s), one or more resistance temperature detector(s), one or more thermistor(s), one or more infrared optical sensor(s), one or more semiconductor-based sensors. In some examples, the sensors 2610 can include one or more flowmeter(s) that measures the flow rate of the coolant through one or more of the lines 2614, 2616, 2618, 2626, 2628, 2630. In some examples, the sensors 2610 can include one or more thermal mass flow sensor(s), Coriolis flow sensor(s), a differential pressure flow sensor(s), a magnetic flowmeter(s), a multiphase flowmeter(s), an ultrasonic flowmeter(s), and/or one or more vortex flowmeter(s). Additionally or alternatively, the sensors 2610 can have one or more pressure sensors, one or more liquid-level sensors, and/or any other suitable type of sensors.

The lines 2614, 2616, 2618, 2626, 2628, 2630 are conduits (e.g., tubes, pipes, etc.) that contain and move liquid coolant between various components of the liquid coolant distribution system 2600. In some examples, some or all of the lines 2614, 2616, 2618, 2626, 2628, 2630 can be implemented by flexible tubes (e.g., rubber tubes, plastic tubes, etc.). Additionally or alternatively, one or both of the lines 2614, 2616, 2618, 2626, 2628, 2630 can be rigid or substantially rigid tubes (e.g., metal piping, plastic tubes, etc.). In some examples, the lines 2614, 2616, 2618, 2626, 2628, 2630 can be insulated to reduce heat transfer between the liquid coolant and the ambient environment of the liquid coolant distribution system 2600. In some examples, the lines 2614, 2616, 2618, 2626, 2628, 2630 can include sealing features (e.g., seals, gaskets, etc.) to prevent liquid coolant in the 2614, 2616, 2618, 2626, 2632, 2634 from leaking. In the illustrated example of FIG. 26, the lines 2614, 2626 are coupled to the inlet 1810 and the outlet 1812, respectively. In some examples, the coupling between the lines 2614, 2626 and the inlet 1810 and the outlet 1812 can include quick disconnect (QD) connectors. In some such examples, the inlet 1810 and/or the outlet 1812 include a togglable self-lock mechanism, which can be enabled/disabled to enable the coupling of the lines 2614, 2626, respectively. In other examples, the lines 2614, 2626 can be coupled to the inlet 1810 and the outlet 1812, respectively. In some examples, the lines 2614, 2626 and/or the valves 2636, 2638 can be absent (e.g., the chassis 1800 does not include a liquid coolant system, etc.).

The valves 2620, 2622, 2632, 2634, 2636, 2638 regulate (e.g., throttles, etc.) the flow rate and pressure of liquid coolant through the lines 2614, 2616, 2618, 2626, 2628, 2630, respectively. In some examples, the valves 2620, 2622, 2632, 2634 can be used to adjust the flow rate of the coolant based on the cooling demand (e.g., cooling needs, heat output, etc.) of the power supplies and/or compute components associated with the heat exchangers 1814, 1816. In some examples, the valves 2636, 2638 control the flow rate of liquid coolant through a cooling system associated with the chassis 1800. For example, the position of the first valve 2620 and/or the third valve 2632 can be used to control the flow rate of liquid coolant through the first heat exchanger 1814. For example, the position of the second valve 2622 and/or the fourth valve 2634 can be used to control flow rate of liquid coolant through the second heat exchanger 1816.

The cooling system controller circuitry 2602 is communicatively coupled to the pump 2608, the sensors 2610, and the valves 2620, 2622, 2632, 2634, 2636, 2638. In some examples, the cooling system controller circuitry 2602 can control the position of the valves 2620, 2622, 2632, 2634 based on one or more outputs of the sensors 2610. For example, the cooling system controller circuitry 2602 can estimate a cooling demand based on a temperature of the power supplies associated with the heat exchangers 1814, 1816, based on the power output of the power supplies associated with the heat exchangers 1814, 1816, based on power input of the power supplies associated with the heat exchangers 1814, 1816, based on a temperature and/or flow speed of the exhaust air into the heat exchangers 1814, 1816. In some examples, the cooling system controller circuitry 2602 can determine cooling instructions based on the determined cooling demand(s). In some examples, the cooling system controller circuitry 2602 can be based on the cooling instructions based on information relating to the workload on the compute components 1804. In some examples, the cooling system controller circuitry 2602 can control the position of one or more of the valves 2620, 2622, 2632, 2634, 2636, 2638, and/or the power input to the pump 2608 based on the determined cooling instructions. In some examples, the cooling system controller circuitry 2602 can cause the heat exchangers 1814, 1816 to exhaust air at a temperature approximately equal to the temperature of the ambient environment. The cooling system controller circuitry 2602 is described below in additional detail in conjunction with FIG. 27.

FIG. 27 is a block diagram of an example implementation of the cooling system controller circuitry 2602 of FIG. 26 to operate the liquid coolant distribution system 2600 of FIG. 26. In the illustrated example of FIG. 27, the cooling system controller circuitry 2602 includes example interface circuitry 2702, example cooling demand determiner circuitry 2704, example instruction generator circuitry 2706, and example system controller circuitry 2708. The cooling system controller circuitry 2602 of FIG. 27 may be instantiated (e.g., creating an instance of, bring into being for any length of time, materialize, implement, etc.) by programmable circuitry such as a Central Processor Unit (CPU) executing first instructions. Additionally or alternatively, the cooling system controller circuitry 2602 of FIG. 27 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 27 may, thus, be instantiated at the same or different times. Some or all of the circuitry of FIG. 27 may be instantiated, for example, in one or more threads executing concurrently on hardware and/or in series on hardware. Moreover, in some examples, some or all of the circuitry of FIG. 27 may be implemented by microprocessor circuitry executing instructions and/or FPGA circuitry performing operations to implement one or more virtual machines and/or containers.

The interface circuitry 2702 accesses, requests, and/or receives sensor data from sensors associated with the chassis (e.g., the chassis 1800 of FIGS. 18 and 26, etc.) and/or the heat exchangers 1814, 1816. For example, the interface circuitry 2702 can receive sensor data from the sensors 2610. In some examples, the interface circuitry 2702 can receive temperature sensor data (e.g., one or more temperature(s) of one or more of the compute components 1804 of the chassis 1800, one or more temperature(s) of one or more power supplies of the chassis 1800, an ambient temperature of the chassis 1800, etc.). In some examples, the interface circuitry 2702 can receive flow rate sensor data (e.g., a flow rate of liquid coolant through the cooling system 1806 of the chassis 1800, a rate of liquid coolant through one or more of the lines 2614, 2616, 2618, 2626, 2628, 2630, a flow rate of exhaust air from one or more of the power supplies of the chassis 1800, etc.). Additionally or alternatively, the interface circuitry 2702 can receive any other suitable sensor data (e.g., pressure data, etc.). In some examples, the interface circuitry 2702 can convert the data received from the sensors 2610 into a numerical form (e.g., human-readable, etc.).

Additionally or alternatively, the interface circuitry 2702 can access workload distribution information associated with one or more the compute units of the chassis 1800. For example, the interface circuitry 2702 can access information relating to a workload on one or more of the compute units of the chassis 1800. For example, the interface circuitry 2702 can access one or more databases associated with the chassis 1800 and/or an operator of the chassis 1800 to determine a current and/or upcoming workload on the compute units of the chassis 1800. In other examples, the interface circuitry 2702 can access the workload distribution information in any other suitable manner. In some examples, the interface circuitry 2702 is instantiated by programmable circuitry executing interface instructions and/or configured to perform operations such as those represented by the flowcharts of FIGS. 28A and 28B.

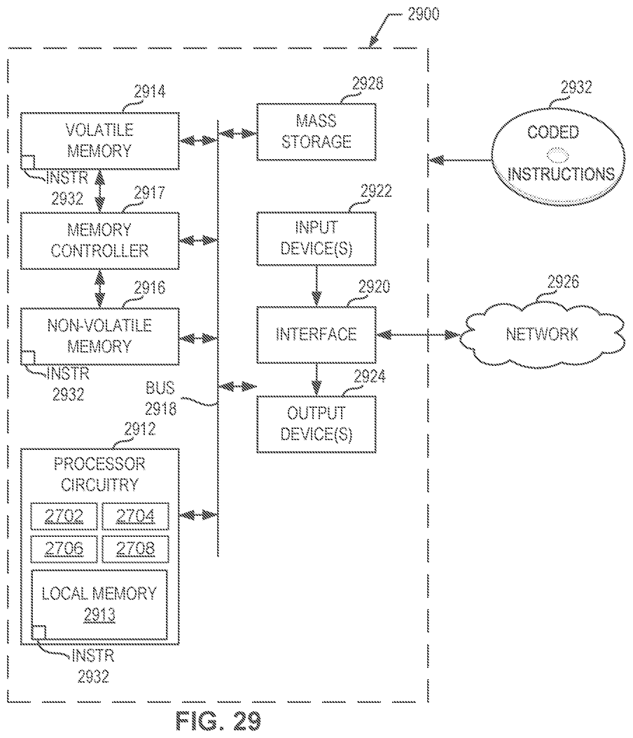

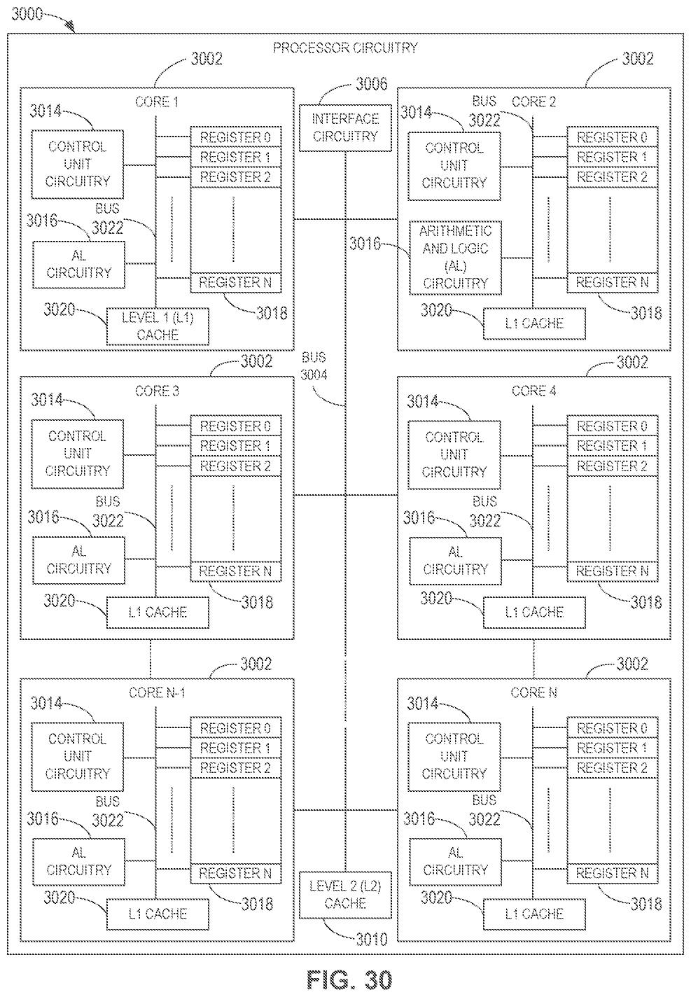

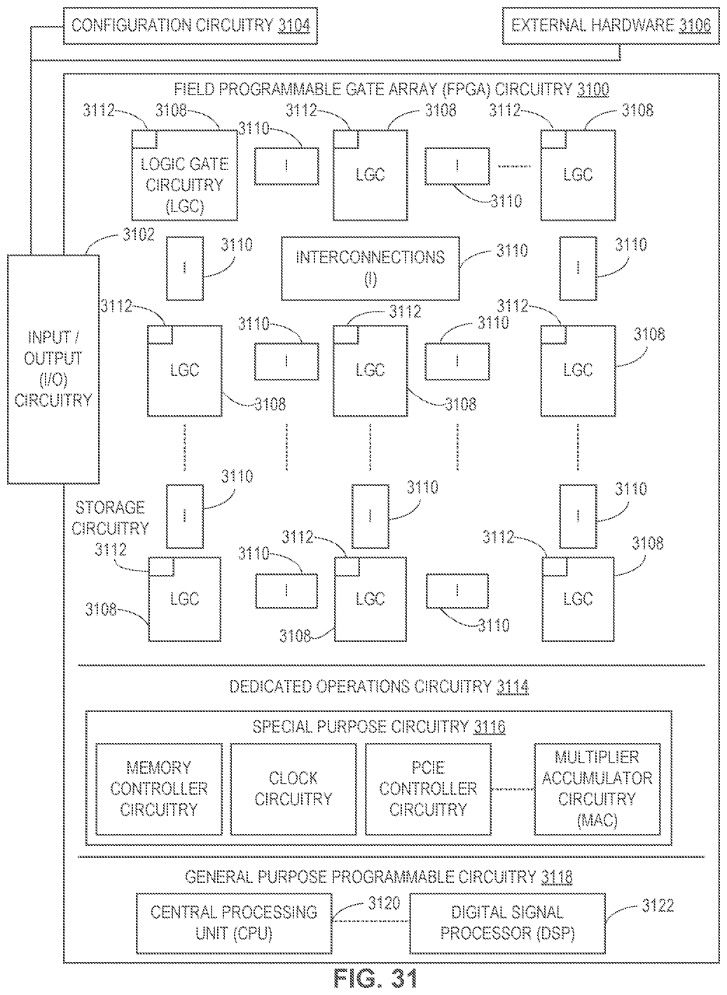

In some examples, the cooling system controller circuitry 2602 includes means for interfacing. For example, the means for interfacing may be implemented by interface circuitry 2702. In some examples, the interface circuitry 2702 may be instantiated by programmable circuitry such as the example programmable circuitry 2912 of FIG. 29. For instance, the interface circuitry 2702 may be instantiated by the example microprocessor 3000 of FIG. 30 executing machine executable instructions such as those implemented by at least blocks 2802, 2804 of FIG. 28A and blocks 2816, 2822 of FIG. 28B. In some examples, the cooling system controller circuitry 2602 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the interface circuitry 2702 may be instantiated by any other combination of hardware, software, and/or firmware. For example, the interface circuitry 2702 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The cooling demand determiner circuitry 2704 determines the cooling demand on one or more power supplies (e.g., the power supply assemblies 2000, 2302 of FIG. 23, etc.) of the chassis 1800 based on workload distribution and sensor data accessed by the interface circuitry 2702. For example, the cooling demand determiner circuitry 2704 can determine the cooling demand for each of the components associated ones of the heat exchangers 1814, 1816 (e.g., a cooling demand of components exhausting air via the first slot 1808A, a cooling demand of components exhausting air via the second slot 1808B, etc.). In some examples, the cooling demand determiner circuitry 2704 can determine the cooling demand based on a current temperature of a power supply, a flow rate of exhaust air through the power supply, a temperature of the exhaust air leaving a power supply, an ambient temperature received from the sensors 2610. Additionally or alternatively, the cooling demand determiner circuitry 2704 can determine the cooling demand based on an upcoming and/or current workload on a compute component associated with one or more of the power supplies (e.g., a processor powered by a power supply upstream of the heat exchangers 1814, 1816, etc.).

In some examples, the cooling demand determiner circuitry 2704 can determine the cooling demand as an energy quantity (e.g., an amount of heat to be dissipated, etc.), a power quantity (e.g., a rate of heat to be dissipated, etc.), and/or a flow rate value (e.g., a flow rate of coolant required to cool one or more of the power supplies). In some examples, the cooling demand determiner circuitry 2704 can determine the cooling demand based on a look-up table (e.g., a cooling demand as an output of the look-up table, sensor data and/or workload information as an input of the look-up table, etc.). Additionally or alternatively, the cooling demand determiner circuitry 2704 can include and/or be implemented by a machine-learning model with the sensor data and/or workload information as an input and a cooling demand as an output. In some examples, the cooling demand determiner circuitry 2704 can determine the cooling demand of the power supplies in any other suitable manner (e.g., based on user input, etc.). In some examples, the cooling demand determiner circuitry 2704 is instantiated by programmable circuitry executing coolant determiner instructions and/or configured to perform operations such as those represented by the flowcharts of FIGS. 28A and 28B.

In some examples, the cooling system controller circuitry 2602 includes means for analyzing a workload. For example, the means for analyzing a workload may be implemented by the cooling demand determiner circuitry 2704. In some examples, the cooling demand determiner circuitry 2704 may be instantiated by programmable circuitry such as the example programmable circuitry 2912 of FIG. 29. For instance, the cooling demand determiner circuitry 2704 may be instantiated by the example microprocessor 3000 of FIG. 30 executing machine executable instructions such as those implemented by at least block 2806 of FIG. 28A and blocks 2818, 2824, 2828, 2829, 2832 of FIG. 28B. In some examples, the cooling demand determiner circuitry 2704 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the cooling demand determiner circuitry 2704 may be instantiated by any other combination of hardware, software, and/or firmware. For example, the cooling demand determiner circuitry 2704 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The instruction generator circuitry 2706 determines (e.g., generates, creates, etc.) cooling instructions based on cooling demand. For example, the instruction generator circuitry 2706 can determine instructions for one or more of the pump 2608 and/or valves 2620, 2622, 2632, 2634, 2636, 2638 based on the determined cooling demand determined during the execution of block 2806. In some examples, the cooling instruction(s) determined by the instruction generator circuitry 2706 can include an instruction to change the position(s) of one or more of the valves 2620, 2622, 2632, 2634, 2636, 2638, a power output of the pump 2608, and/or a speed of one or more of the fans associated with the chassis 1800 (e.g., the fan 2006 of FIG. 20, etc.). In other examples, the instruction generator circuitry 2706 can determine any other suitable instructions. For example, the instruction generator circuitry 2706 can determine a cooling instruction via one or more mathematical calculations, a look-up table, and/or a machine-learning model. In other examples, the instruction generator circuitry 2706 can determine the cooling instructions in any other suitable manner. In some examples, the instruction generator circuitry 2706 is instantiated by programmable circuitry executing instruction generator instructions and/or configured to perform operations such as those represented by the flowcharts of FIGS. 28A and 28B.

In some examples, the cooling system controller circuitry 2602 includes means for generating instructions. For example, the means for generating instructions may be implemented by the instruction generator circuitry 2706. In some examples, the instruction generator circuitry 2706 may be instantiated by programmable circuitry such as the example programmable circuitry 2912 of FIG. 29. For instance, the instruction generator circuitry 2706 may be instantiated by the example microprocessor 3000 of FIG. 30 executing machine executable instructions such as those implemented by at least block 2808 of FIG. 28A. In some examples, the instruction generator circuitry 2706 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the instruction generator circuitry 2706 may be instantiated by any other combination of hardware, software, and/or firmware. For example, the instruction generator circuitry 2706 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The system controller circuitry 2708 the system controller circuitry 2708 sends the instructions to the pump 2608 and/or valves 2620, 2622, 2632, 2634, 2636, 2638 based on the cooling instructions. For example, the system controller circuitry 2708 can send a signal (e.g., a hydraulic signal, a pneumatic signal, an electronic signal, etc.) to one or more controllable feature(s) (e.g., an actuator, etc.) of the valves 2620, 2622, 2632, 2634, 2636, 2638. In other examples, the system controller circuitry 2708 can send an instruction to control the position of the valves 2620, 2622, 2632, 2634, 2636, 2638 via a direct mechanical connection (e.g., a control arm, etc.). In some examples, the system controller circuitry 2708 can control a flow rate of liquid coolant through the pump 2608 by sending a signal (e.g., a hydraulic signal, a pneumatic signal, an electronic signal, etc.). In some such examples, the system controller circuitry 2708 can send an instruction to increase and/or decrease a power input and/or output of the pump 2608. In some examples, the system controller circuitry 2708 is instantiated by programmable circuitry executing system controller instructions and/or configured to perform operations such as those represented by the flowcharts of FIGS. 28A and 28B.

In some examples, the cooling system controller circuitry 2602 includes means for controlling a cooling system. For example, the means for controlling a cooling system may be implemented by the system controller circuitry 2708. In some examples, the system controller circuitry 2708 may be instantiated by programmable circuitry such as the example programmable circuitry 2912 of FIG. 29. For instance, the system controller circuitry 2708 may be instantiated by the example microprocessor 3000 of FIG. 30 executing machine executable instructions such as those implemented by at least block 2810, 2812 of FIG. 28A and blocks 2820, 2826, 2830, 2834 of FIG. 28B. In some examples, the system controller circuitry 2708 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the system controller circuitry 2708 may be instantiated by any other combination of hardware, software, and/or firmware. For example, the system controller circuitry 2708 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the cooling system controller circuitry 2602 of FIG. 26 is illustrated in FIG. 27, one or more of the elements, processes, and/or devices illustrated in FIG. 27 may be combined, divided, re-arranged, omitted, eliminated, and/or implemented in any other way. Further, the interface circuitry 2702, the cooling demand determiner circuitry 2704, the instruction generator circuitry 2706, the system controller circuitry 2708, and/or, more generally, the example cooling system controller circuitry 2602 of FIG. 27, may be implemented by hardware alone or by hardware in combination with software and/or firmware. Thus, for example, any of the interface circuitry 2702, the cooling demand determiner circuitry 2704, the instruction generator circuitry 2706, the system controller circuitry 2708, and/or, more generally, the example cooling system controller circuitry 2602, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example cooling system controller circuitry 2602 of FIG. 27 may include one or more elements, processes, and/or devices in addition to, or instead of, those illustrated in FIG. 27, and/or may include more than one of any or all of the illustrated elements, processes and devices.

Flowcharts representative of example machine readable instructions, which may be executed by programmable circuitry to implement and/or instantiate the cooling system controller circuitry 2602 of FIG. 27 and/or representative of example operations which may be performed by programmable circuitry to implement and/or instantiate the cooling system controller circuitry 2602 of FIG. 27, are shown in FIGS. 28A and 28B. The machine readable instructions may be one or more executable programs or portion(s) of one or more executable programs for execution by programmable circuitry such as the programmable circuitry 2912 shown in the example programmable circuitry platform 2900 discussed below in connection with FIG. 29 and/or may be one or more function(s) or portion(s) of functions to be performed by the example programmable circuitry (e.g., an FPGA) discussed below in connection with FIGS. 30 and/or 31. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowcharts illustrated in FIG. 28A and FIG. 28B, many other methods of implementing the example cooling system controller circuitry 2602 may alternatively be used. For example, the order of execution of the blocks of the flowcharts may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 28A and FIG. 28B may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 28A is a flowchart representative of example machine readable instructions and/or example operations 2800 that may be executed, instantiated, and/or performed by programmable circuitry to operate the liquid coolant distribution system 2600 of FIG. 26. The example machine-readable instructions and/or the example operations 2800 of FIG. 28A begin at block 2802, at which the interface circuitry 2702 accesses the sensor data associated with a chassis (e.g., the chassis 1800 of FIGS. 18 and 26, etc.). For example, the interface circuitry 2702 can receive sensor data from the sensors 2610. In some examples, the interface circuitry 2702 can receive temperature sensor data (e.g., one or more temperature(s) of one or more of the compute components 1804 of the chassis 1800, one or more temperature(s) of one or more power supplies of the chassis 1800, an ambient temperature of the chassis 1800, etc.). In some examples, the interface circuitry 2702 can receive flow rate sensor data (e.g., a flow rate of liquid coolant through the cooling system 1806 of the chassis 1800, a rate of liquid coolant through one or more of the lines 2614, 2616, 2618, 2626, 2628, 2630, a flow rate of exhaust air from one or more of the power supplies of the chassis 1800, etc.). Additionally or alternatively, the interface circuitry 2702 can receive any other suitable sensor data (e.g., pressure data, etc.). In some examples, the interface circuitry 2702 can convert the data received from the sensors 2610 into a numerical form (e.g., human-readable, etc.).

At block 2804, the interface circuitry 2702 accesses workload distribution information. For example, the interface circuitry 2702 can access information relating to a workload on one or more of the compute units of the chassis 1800. For example, the interface circuitry 2702 can access one or more databases associated with the chassis 1800 and/or an operator of the chassis 1800 to determine a current and/or upcoming workload on the compute units of the chassis 1800. In other examples, the interface circuitry 2702 can access the workload distribution information in any other suitable manner. In some examples, block 2804 is omitted and control of the system is based on the sensor data without regard to workload information.

At block 2806, the cooling demand determiner circuitry 2704 determines the cooling demand on one or more power supplies of the chassis based on workload distribution information and/or sensor data. For example, the cooling demand determiner circuitry 2704 can determine the cooling demand for each of the components associated ones of the heat exchangers 1814, 1816 (e.g., a cooling demand of components exhausting air via the first slot 1808A, a cooling demand of components exhausting air via the second slot 1808B, etc.). In some examples, the cooling demand determiner circuitry 2704 can determine the cooling demand based on a current temperature of a power supply, a flow rate of exhaust air through the power supply, a temperature of the exhaust air leaving a power supply, an ambient temperature received from the sensors 2610. In some examples, the cooling demand determiner circuitry 2704 can determine a cooling demand based to enable the heat exchangers 1814, 1816 to exhaust air at a temperature substantially equal to the ambient temperature.

Additionally or alternatively, the cooling demand determiner circuitry 2704 can determine the cooling demand based on an upcoming and/or current workload on a compute component associated with one or more of the power supplies (e.g., a processor powered by a power supply upstream of the heat exchangers 1814, 1816, etc.). In some examples, the cooling demand determiner circuitry 2704 can determine the cooling demand as an energy quantity (e.g., an amount of heat to be dissipated, etc.), a power quantity (e.g., a rate of heat to be dissipated, etc.), and/or a flow rate value (e.g., a flow rate of coolant required to cool one or more of the power supplies). In some examples, the cooling demand determiner circuitry 2704 can determine the cooling demand based on a look-up table (e.g., a cooling demand as an output of the look-up table, sensor data and/or workload information as an input of the look-up table, etc.). Additionally or alternatively, the cooling demand determiner circuitry 2704 can use a machine-learning model with the sensor data and/or workload information as an input and a cooling demand as an output. In some examples, the cooling demand determiner circuitry 2704 can determine the cooling demand of the power supplies in any other suitable manner (e.g., based on a user input, etc.).

At block 2808, the instruction generator circuitry 2706 determines cooling instructions based on cooling demand. For example, the instruction generator circuitry 2706 can determine instructions for one or more of the pump 2608 and/or valves 2620, 2622, 2632, 2634, 2636, 2638 based on the determined cooling demand determined during the execution of block 2806. In some examples, the cooling instruction(s) determined by the instruction generator circuitry 2706 can include an instruction to change the position of one or more of the valves 2620, 2622, 2632, 2634, 2636, 2638, a power output of the pump 2608, and/or a speed of one or more of the fans associated with the chassis 1800 (e.g., the fan 2006 of FIG. 20, etc.). In other examples, the instruction generator circuitry 2706 can determine any other suitable instructions. For example, the instruction generator circuitry 2706 can determine a cooling instruction via one or more mathematical calculations, a look-up table, and/or a machine-learning model. In other examples, the instruction generator circuitry 2706 can determine the cooling instructions in any other suitable manner.

At block 2810, the system controller circuitry 2708 sends the instructions to the pump 2608 and/or valves 2620, 2622, 2632, 2634, 2636, 2638 based on the cooling instructions. For example, the system controller circuitry 2708 can send a signal (e.g., a hydraulic signal, a pneumatic signal, an electronic signal, etc.) to one or more controllable feature(s) (e.g., an actuator, etc.) of the valves 2620, 2622, 2632, 2634, 2636, 2638. In other examples, the system controller circuitry 2708 can send an instruction to control the position of the valves 2620, 2622, 2632, 2634, 2636, 2638 via a direct mechanical connection (e.g., a control arm, etc.). In some examples, the system controller circuitry 2708 can control the flow rate of the pump 2608 by sending a signal (e.g., a hydraulic signal, a pneumatic signal, an electronic signal, etc.). In some such examples, the system controller circuitry 2708 can send an instruction to increase and/or decrease a power input and/or output of the pump 2608.

At block 2812, the system controller circuitry 2708 determines if the coolant distribution is to be updated. For example, the system controller circuitry 2708 can determine to update the coolant distribution based on a change in output of the sensors 2610 detected by the interface circuitry 2702 and/or a change in the workload on the compute components 1804 of the chassis 1800. Additionally or alternatively, the system controller circuitry 2708 can determine to update the coolant distribution based on a user setting and/or a user command. Additionally or alternatively, the system controller circuitry 2708 can determine to update the coolant distribution periodically (e.g., every minute, every hour, every day, etc.). If the system controller circuitry 2708 determines the coolant distribution is to be updated, the operations 2800 return to block 2802. If the system controller circuitry 2708 determines the coolant distribution is not to be updated, the operations 2800 end.

FIG. 28B is a flowchart representative of example machine readable instructions and/or example operations 2814 that may be executed, instantiated, and/or performed by programmable circuitry to operate the first heat exchanger 1814. The example machine-readable instructions and/or the example operations 2814 of FIG. 28B begin at block 2816, at which the interface circuitry 2702 accesses the sensor data associated with a chassis 1800 and/or the first heat exchanger 1814. For example, the interface circuitry 2702 can receive sensor data from one or more of the sensors 2402, 2404, 2406, 2408 of FIG. 24. Additionally or alternatively, the interface circuitry 2702 can receive any other suitable sensor data (e.g., pressure data, etc.). In some examples, the interface circuitry 2702 can convert the data received from the sensors 2402, 2404, 2406, 2408 into a numerical form (e.g., human-readable, etc.).

At block 2818, the cooling demand determiner circuitry 2704 determines if the inlet temperature of the first heat exchanger 1814 is greater than the ambient temperature and less than a first threshold temperature. For example, the cooling demand determiner circuitry 2704 can determine if the temperature output by the first sensor 2402 is greater than an ambient temperature of the first heat exchanger 1814 (e.g., a temperature of a data center including the chassis 1800, etc.) and less than the first threshold temperature. In some examples, the first threshold temperature can be based on a user setting, a type of coolant used by the first heat exchanger 1814, one or more hardware components of the chassis 1800, and/or any other suitable metric. In some examples, the first threshold temperature can be 50 degrees Celsius. Additionally or alternatively, the first threshold temperature can be based on a temperature of municipal water available for cooling the liquid coolant. If the cooling demand determiner circuitry 2704 determines the inlet temperature of the first heat exchanger 1814 is greater than the ambient temperature and less than the first threshold temperature, the operations 2814 advance to block 2818. If the cooling demand determiner circuitry 2704 determines the inlet temperature of the first heat exchanger 1814 is not greater than the ambient temperature and less than the first threshold temperature, the operations 2814 advance to block 2824.

At block 2820, the system controller circuitry 2708 sets the system (e.g., the system 2600, etc.) to have a first coolant flow rate and/or a coolant inlet temperature to ambient temperature. For example, the system controller circuitry 2708 can, by sending an instruction to a pump associated with the first heat exchanger 1814 (e.g., 2608 of FIG. 26, etc.) to change a flow rate of coolant flow through the first heat exchanger 1814. For example, the system controller circuitry 2708 can, by sending an instruction to a CDU associated with the first heat exchanger 1814 (e.g., 2608 of FIG. 26, etc.) to change a temperature of coolant flowing through the first heat exchanger 1814 to an ambient temperature. In some examples, the system controller circuitry 2708 can cause the first heat exchanger 1814 to operate in a minimum coolant flow rate available to the chassis 1800 to reduce the power use of the first heat exchanger 1814, etc. In some examples, the system controller circuitry 2708 can, via feedback from the third sensor 2406 and/or the fourth sensor 2408, monitor the temperature of the coolant flowing through the first heat exchanger 1814.

At block 2822, the interface circuitry 2702 determines if the outlet temperature of the first heat exchanger 1814 is less than the inlet temperature of the first heat exchanger 1814. For example, the interface circuitry 2702 determines if the first heat exchanger 1814 is able to cool the air flow from the chassis 1800 at the currently set coolant flow rate and coolant temperature by comparing the inlet temperature of the temperature output by the first sensor 2402 to the temperature output by the second sensor 2404. Additionally or alternatively, the interface circuitry 2702 can determine if the first heat exchanger 1814 is reducing the temperature of the air flow flowing therethrough at the currently set coolant flow rate and coolant temperature. If the interface circuitry 2702 determines the outlet temperature of the first heat exchanger 1814 is less than the inlet temperature of the first heat exchanger 1814, the operations 2814 advance to block 2834. If the interface circuitry 2702 determines the outlet temperature of the first heat exchanger 1814 is not less than the inlet temperature of the first heat exchanger 1814, the operations 2814 return to block 2818.

At block 2824, the cooling demand determiner circuitry 2704 determines if the inlet temperature of the first heat exchanger 1814 is greater than the first threshold and less than a second threshold temperature. For example, the cooling demand determiner circuitry 2704 can determine if the temperature output by the first sensor 2402 is greater than the first threshold temperature and less than a second threshold temperature that is greater than the first threshold temperature. In some examples, the second threshold temperature can be based on a user setting, a type of coolant used by the first heat exchanger 1814, one or more hardware components of the chassis 1800, the first threshold temperature, and/or any other suitable metric. In some examples, the second threshold temperature can be 70 degrees Celsius. If the cooling demand determiner circuitry 2704 determines the inlet temperature of the first heat exchanger 1814 is greater than the first threshold temperature and less than the second threshold temperature, the operations 2814 advance to block 2826. If the cooling demand determiner circuitry 2704 determines the inlet temperature of the first heat exchanger 1814 is not greater than the first threshold temperature and less than the second threshold temperature, the operations 2814 advance to block 2830.

At block 2826, the system controller circuitry 2708 sets the system (e.g., the system 2600, etc.) to have a second coolant flow rate and/or a coolant inlet temperature to a below ambient temperature. For example, the system controller circuitry 2708 can, by sending an instruction to a pump associated with the first heat exchanger 1814 (e.g., 2608 of FIG. 26, etc.) to change increase the rate of coolant flow through the first heat exchanger 1814 to a second flow rate above the flow rate associated with block 2820. For example, the system controller circuitry 2708 can, by sending an instruction to a CDU associated with the first heat exchanger 1814 (e.g., 2608 of FIG. 26, etc.) to change a temperature of coolant flowing through the first heat exchanger 1814 to a below ambient temperature. In some examples, the system controller circuitry 2708 can, via feedback from the third sensor and/or the fourth sensor 2408 monitor the temperature of the coolant flowing through the first heat exchanger 1814.

At block 2828, the interface circuitry 2702 determines if the outlet temperature of the first heat exchanger 1814 is less than the inlet temperature of the first heat exchanger 1814. For example, the interface circuitry 2702 determines if the first heat exchanger 1814 is able to cool the air flow from the chassis 1800 at the currently set coolant flow rate and coolant temperature by comparing the inlet temperature of the temperature output by the first sensor 2402 to the temperature output by the second sensor 2404. Additionally or alternatively, the interface circuitry 2702 can determine if the first heat exchanger 1814 is reducing the temperature of the flow flowing therethrough at the currently set coolant flow rate and coolant temperature. If the interface circuitry 2702 determines the outlet temperature of the first heat exchanger 1814 is less than the inlet temperature of the first heat exchanger 1814, the operations 2814 advance to block 2834. If the interface circuitry 2702 determines the outlet temperature of the first heat exchanger 1814 is not less than the inlet temperature of the first heat exchanger 1814, the operations 2814 return to block 2824.

At block 2829, the cooling demand determiner circuitry 2704 determines if the inlet temperature of the first heat exchanger 1814 is greater than the second threshold temperature. For example, the cooling demand determiner circuitry 2704 can determine if the temperature output by the first sensor 2402 is greater than a second threshold temperature. If the cooling demand determiner circuitry 2704 determines the inlet temperature of the first heat exchanger 1814 is greater than the second threshold temperature, the operations 2814 advance to block 2830. If the cooling demand determiner circuitry 2704 determines the inlet temperature of the first heat exchanger 1814 is not greater than the second threshold temperature (e.g., the inlet temperature of the first heat exchanger 1814 is less than the second threshold temperature, the first threshold temperature and the ambient temperature of the first heat exchanger 1814, etc.), the operations 2814 advance to block 2830.

At block 2830, the system controller circuitry 2708 sets the system (e.g., the system 2600, etc.) to have a third coolant flow rate and/or a coolant inlet temperature to a low ambient temperature. For example, the system controller circuitry 2708 can, by sending an instruction to a pump associated with the first heat exchanger 1814 (e.g., 2608 of FIG. 26, etc.) to change increase the rate of coolant flow through the first heat exchanger 1814 to a third flow rate above the flow rate associated with blocks 2820 and 2826. In some examples, the system controller circuitry 2708 can set the coolant flow rate as a maximum flow rate the system 2600 is capable of. For example, the system controller circuitry 2708 can, by sending an instruction to a CDU associated with the first heat exchanger 1814 (e.g., 2608 of FIG. 26, etc.) to change a temperature of coolant flowing through the first heat exchanger 1814 to a below ambient temperature that is lower than the temperature associated with block 2826. In some examples, the system controller circuitry 2708 can set the coolant temperature as a minimum temperature the system 2600 is capable of. In some examples, the system controller circuitry 2708 can, via feedback from the third sensor 2406 and/or the fourth sensor 2408, monitor the temperature of the coolant flowing through the first heat exchanger 1814.

At block 2832, the interface circuitry 2702 determines if the outlet temperature of the first heat exchanger 1814 is less than the inlet temperature of the first heat exchanger 1814. For example, the interface circuitry 2702 determines if the first heat exchanger 1814 is able to cool the air flow from the chassis 1800 at the currently set coolant flow rate and coolant temperature by comparing the inlet temperature of the temperature output by the first sensor 2402 to the temperature output by the second sensor 2404. Additionally or alternatively, the interface circuitry 2702 can determine if the first heat exchanger 1814 is reducing the temperature of the flow flowing therethrough at the currently set coolant flow rate and coolant temperature. If the interface circuitry 2702 determines the outlet temperature of the first heat exchanger 1814 is less than the inlet temperature of the first heat exchanger 1814, the operations 2814 advance to block 2834. If the interface circuitry 2702 determines the outlet temperature of the first heat exchanger 1814 is not less than the inlet temperature of the first heat exchanger 1814, the operations 2814 return to block 2824.

At block 2834, the system controller circuitry 2708 determines if the coolant temperature and/or coolant flowrate is to be updated. For example, the system controller circuitry 2708 can determine to update the coolant distribution based on a change in output of the sensors 2402, 2404, 2406, 2408 detected by the interface circuitry 2702. Additionally or alternatively, the system controller circuitry 2708 can determine to update the coolant distribution based on a user setting and/or a user command. Additionally or alternatively, the system controller circuitry 2708 can determine to update the coolant distribution periodically (e.g., every minute, every hour, every day, etc.). If the system controller circuitry 2708 determines the coolant distribution is to be updated, the operations 2814 return to block 2816. If the system controller circuitry 2708 determines the coolant distribution is not to be updated, the operations 2814 end.

FIG. 29 is a block diagram of an example programmable circuitry platform 2900 structured to execute and/or instantiate the example machine-readable instructions and/or the example operations of FIGS. 28A and 28B to implement the cooling system controller circuitry 2602 of FIG. 27. The programmable circuitry platform 2900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 2900 of the illustrated example includes programmable circuitry 2912. The programmable circuitry 2912 of the illustrated example is hardware. For example, the programmable circuitry 2912 can be implemented by one or more integrated circuits, logic circuits, FPGAs, microprocessors, CPUs, GPUs, DSPs, and/or microcontrollers from any desired family or manufacturer. The programmable circuitry 2912 may be implemented by one or more semiconductor based (e.g., silicon based) devices. In this example, the programmable circuitry 2912 implements the interface circuitry 2702, the cooling demand determiner circuitry 2704, the instruction generator circuitry 2706, and the system controller circuitry 2708.

The programmable circuitry 2912 of the illustrated example includes a local memory 2913 (e.g., a cache, registers, etc.). The programmable circuitry 2912 of the illustrated example is in communication with main memory 2914, 2916, which includes a volatile memory 2914 and a non-volatile memory 2916, by a bus 2918. The volatile memory 2914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2916 may be implemented by flash memory and/or any other desired type of memory device. Access to the main memory 2914, 2916 of the illustrated example is controlled by a memory controller 2917. In some examples, the memory controller 2917 may be implemented by one or more integrated circuits, logic circuits, microcontrollers from any desired family or manufacturer, or any other type of circuitry to manage the flow of data going to and from the main memory 2914, 2916.

The programmable circuitry platform 2900 of the illustrated example also includes interface circuitry 2920. The interface circuitry 2920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2922 are connected to the interface circuitry 2920. The input device(s) 2922 permit(s) a user (e.g., a human user, a machine user, etc.) to enter data and/or commands into the programmable circuitry 2912. The input device(s) 2922 can be implemented by, for example, an audio sensor, a microphone, a camera (still or video), a keyboard, a button, a mouse, a touchscreen, a trackpad, a trackball, an isopoint device, and/or a voice recognition system.

One or more output devices 2924 are also connected to the interface circuitry 2920 of the illustrated example. The output device(s) 2924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2920 of the illustrated example, thus, typically includes a graphics driver card, a graphics driver chip, and/or graphics processor circuitry such as a GPU.

The interface circuitry 2920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 2900 of the illustrated example also includes one or more mass storage discs or devices 2928 to store firmware, software, and/or data. Examples of such mass storage discs or devices 2928 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 2932, which may be implemented by the machine readable instructions of FIGS. 28A and 28B, may be stored in the mass storage device 2928, in the volatile memory 2914, in the non-volatile memory 2916, and/or on at least one non-transitory computer readable storage medium such as a CD or DVD which may be removable.

FIG. 30 is a block diagram of an example implementation of the programmable circuitry 2912 of FIG. 29. In this example, the programmable circuitry 2912 of FIG. 29 is implemented by a microprocessor 3000. For example, the microprocessor 3000 may be a general-purpose microprocessor (e.g., general-purpose microprocessor circuitry). The microprocessor 3000 executes some or all of the machine-readable instructions of the flowcharts of FIGS. 28A and 28B to effectively instantiate the circuitry of FIG. 27 as logic circuits to perform operations corresponding to those machine readable instructions. In some such examples, the circuitry of FIG. 27 is instantiated by the hardware circuits of the microprocessor 3000 in combination with the machine-readable instructions. For example, the microprocessor 3000 may be implemented by multi-core hardware circuitry such as a CPU, a DSP, a GPU, an XPU, etc. Although it may include any number of example cores 3002 (e.g., 1 core), the microprocessor 3000 of this example is a multi-core semiconductor device including N cores. The cores 3002 of the microprocessor 3000 may operate independently or may cooperate to execute machine readable instructions. For example, machine code corresponding to a firmware program, an embedded software program, or a software program may be executed by one of the cores 3002 or may be executed by multiple ones of the cores 3002 at the same or different times. In some examples, the machine code corresponding to the firmware program, the embedded software program, or the software program is split into threads and executed in parallel by two or more of the cores 3002. The software program may correspond to a portion or all of the machine readable instructions and/or operations represented by the flowcharts of FIGS. 28A and 28B.

The cores 3002 may communicate by a first example bus 3004. In some examples, the first bus 3004 may be implemented by a communication bus to effectuate communication associated with one(s) of the cores 3002. For example, the first bus 3004 may be implemented by at least one of an Inter-Integrated Circuit (I2C) bus, a Serial Peripheral Interface (SPI) bus, a PCI bus, or a PCIe bus. Additionally or alternatively, the first bus 3004 may be implemented by any other type of computing or electrical bus. The cores 3002 may obtain data, instructions, and/or signals from one or more external devices by example interface circuitry 3006. The cores 3002 may output data, instructions, and/or signals to the one or more external devices by the interface circuitry 3006. Although the cores 3002 of this example include example local memory 3020 (e.g., Level 1 (L1) cache that may be split into an L1 data cache and an L1 instruction cache), the microprocessor 3000 also includes example shared memory 3010 that may be shared by the cores (e.g., Level 2 (L2 cache)) for high-speed access to data and/or instructions. Data and/or instructions may be transferred (e.g., shared) by writing to and/or reading from the shared memory 3010. The local memory 3020 of each of the cores 3002 and the shared memory 3010 may be part of a hierarchy of storage devices including multiple levels of cache memory and the main memory (e.g., the main memory 2914, 2916 of FIG. 29). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 3002 may be referred to as a CPU, DSP, GPU, etc., or any other type of hardware circuitry. Each core 3002 includes control unit circuitry 3014, arithmetic and logic (AL) circuitry 3016 (sometimes referred to as an ALU), a plurality of registers 3018, the local memory 3020, and a second example bus 3022. Other structures may be present. For example, each core 3002 may include vector unit circuitry, single instruction multiple data (SIMD) unit circuitry, load/store unit (LSU) circuitry, branch/jump unit circuitry, floating-point unit (FPU) circuitry, etc. The control unit circuitry 3014 includes semiconductor-based circuits structured to control (e.g., coordinate) data movement within the corresponding core 3002. The AL circuitry 3016 includes semiconductor-based circuits structured to perform one or more mathematic and/or logic operations on the data within the corresponding core 3002. The AL circuitry 3016 of some examples performs integer based operations. In other examples, the AL circuitry 3016 also performs floating-point operations. In yet other examples, the AL circuitry 3016 may include first AL circuitry that performs integer-based operations and second AL circuitry that performs floating-point operations. In some examples, the AL circuitry 3016 may be referred to as an Arithmetic Logic Unit (ALU).

The registers 3018 are semiconductor-based structures to store data and/or instructions such as results of one or more of the operations performed by the AL circuitry 3016 of the corresponding core 3002. For example, the registers 3018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 3018 may be arranged in a bank as shown in FIG. 30. Alternatively, the registers 3018 may be organized in any other arrangement, format, or structure, such as by being distributed throughout the core 3002 to shorten access time. The second bus 3022 may be implemented by at least one of an I2C bus, a SPI bus, a PCI bus, or a PCIe bus.

Each core 3002 and/or, more generally, the microprocessor 3000 may include additional and/or alternate structures to those shown and described above. For example, one or more clock circuits, one or more power supplies, one or more power gates, one or more cache home agents (CHAs), one or more converged/common mesh stops (CMS s), one or more shifters (e.g., barrel shifter(s)) and/or other circuitry may be present. The microprocessor 3000 is a semiconductor device fabricated to include many transistors interconnected to implement the structures described above in one or more integrated circuits (ICs) contained in one or more packages.

The microprocessor 3000 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 3000, in the same chip package as the microprocessor 3000 and/or in one or more separate packages from the microprocessor 3000.

FIG. 31 is a block diagram of another example implementation of the programmable circuitry 2912 of FIG. 29. In this example, the programmable circuitry 2912 is implemented by FPGA circuitry 3100. For example, the FPGA circuitry 3100 may be implemented by an FPGA. The FPGA circuitry 3100 can be used, for example, to perform operations that could otherwise be performed by the example microprocessor 3000 of FIG. 30 executing corresponding machine readable instructions. However, once configured, the FPGA circuitry 3100 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 3000 of FIG. 30 described above (which is a general purpose device that may be programmed to execute some or all of the machine readable instructions represented by the flowcharts of FIG. 28A and FIG. 28B but whose interconnections and logic circuitry are fixed once fabricated), the FPGA circuitry 3100 of the example of FIG. 31 includes interconnections and logic circuitry that may be configured, structured, programmed, and/or interconnected in different ways after fabrication to instantiate, for example, some or all of the operations/functions corresponding to the machine readable instructions represented by the flowcharts of FIGS. 28A and 28B. In particular, the FPGA circuitry 3100 may be thought of as an array of logic gates, interconnections, and switches. The switches can be programmed to change how the logic gates are interconnected by the interconnections, effectively forming one or more dedicated logic circuits (unless and until the FPGA circuitry 3100 is reprogrammed). The configured logic circuits enable the logic gates to cooperate in different ways to perform different operations on data received by input circuitry. Those operations may correspond to some or all of the instructions (e.g., the software and/or firmware) represented by the flowcharts of FIGS. 28A and 28B. As such, the FPGA circuitry 3100 may be configured and/or structured to effectively instantiate some or all of the operations/functions corresponding to the machine readable instructions of the flowcharts of FIGS. 28A and 28B as dedicated logic circuits to perform the operations/functions corresponding to those software instructions in a dedicated manner analogous to an ASIC. Therefore, the FPGA circuitry 3100 may perform the operations/functions corresponding to the some or all of the machine readable instructions of FIGS. 28A and 28B faster than the general-purpose microprocessor can execute the same.

In the example of FIG. 31, the FPGA circuitry 3100 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 3100 of FIG. 31 may access and/or load the binary file to cause the FPGA circuitry 3100 of FIG. 31 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3100 of FIG. 31 to cause configuration and/or structuring of the FPGA circuitry 3100 of FIG. 31, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 3100 of FIG. 31 may access and/or load the binary file to cause the FPGA circuitry 3100 of FIG. 31 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3100 of FIG. 31 to cause configuration and/or structuring of the FPGA circuitry 3100 of FIG. 31, or portion(s) thereof.

The FPGA circuitry 3100 of FIG. 31, includes example input/output (I/O) circuitry 3102 to obtain and/or output data to/from example configuration circuitry 3104 and/or external hardware 3106. For example, the configuration circuitry 3104 may be implemented by interface circuitry that may obtain a binary file, which may be implemented by a bit stream, data, and/or machine-readable instructions, to configure the FPGA circuitry 3100, or portion(s) thereof. In some such examples, the configuration circuitry 3104 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 3106 may be implemented by external hardware circuitry. For example, the external hardware 3106 may be implemented by the microprocessor 3000 of FIG. 30.

The FPGA circuitry 3100 also includes an array of example logic gate circuitry 3108, a plurality of example configurable interconnections 3110, and example storage circuitry 3112. The logic gate circuitry 3108 and the configurable interconnections 3110 are configurable to instantiate one or more operations/functions that may correspond to at least some of the machine readable instructions of FIGS. 28A and 28B and/or other desired operations. The logic gate circuitry 3108 shown in FIG. 31 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 3108 to enable configuration of the electrical structures and/or the logic gates to form circuits to perform desired operations/functions. The logic gate circuitry 3108 may include other electrical structures such as look-up tables (LUTs), registers (e.g., flip-flops or latches), multiplexers, etc.

The configurable interconnections 3110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 3108 to program desired logic circuits.

The storage circuitry 3112 of the illustrated example is structured to store result(s) of the one or more of the operations performed by corresponding logic gates. The storage circuitry 3112 may be implemented by registers or the like. In the illustrated example, the storage circuitry 3112 is distributed amongst the logic gate circuitry 3108 to facilitate access and increase execution speed.

The example FPGA circuitry 3100 of FIG. 31 also includes example dedicated operations circuitry 3114. In this example, the dedicated operations circuitry 3114 includes special purpose circuitry 3116 that may be invoked to implement commonly used functions to avoid the need to program those functions in the field. Examples of such special purpose circuitry 3116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 3100 may also include example general purpose programmable circuitry 3118 such as an example CPU 3120 and/or an example DSP 3122. Other general purpose programmable circuitry 3118 may additionally or alternatively be present such as a GPU, an XPU, etc., that can be programmed to perform other operations.

Although FIGS. 30 and 31 illustrate two example implementations of the programmable circuitry 2912 of FIG. 29, many other approaches are contemplated. For example, FPGA circuitry may include an on-board CPU, such as one or more of the example CPU 3120 of FIG. 30. Therefore, the programmable circuitry 2912 of FIG. 29 may additionally be implemented by combining at least the example microprocessor 3000 of FIG. 30 and the example FPGA circuitry 3100 of FIG. 31. In some such hybrid examples, one or more cores 3002 of FIG. 30 may execute a first portion of the machine readable instructions represented by the flowcharts of FIGS. 28A and 28B to perform first operation(s)/function(s), the FPGA circuitry 3100 of FIG. 31 may be configured and/or structured to perform second operation(s)/function(s) corresponding to a second portion of the machine readable instructions represented by the flowcharts of FIGS. 28A and 28B, and/or an ASIC may be configured and/or structured to perform third operation(s)/function(s) corresponding to a third portion of the machine readable instructions represented by the flowcharts of FIGS. 28A and 28B.

It should be understood that some or all of the circuitry of FIG. 27 may, thus, be instantiated at the same or different times. For example, same and/or different portion(s) of the microprocessor 3000 of FIG. 30 may be programmed to execute portion(s) of machine-readable instructions at the same and/or different times. In some examples, same and/or different portion(s) of the FPGA circuitry 3100 of FIG. 31 may be configured and/or structured to perform operations/functions corresponding to portion(s) of machine-readable instructions at the same and/or different times.

In some examples, some or all of the circuitry of FIG. 27 may be instantiated, for example, in one or more threads executing concurrently and/or in series. For example, the microprocessor 3000 of FIG. 30 may execute machine readable instructions in one or more threads executing concurrently and/or in series. In some examples, the FPGA circuitry 3100 of FIG. 31 may be configured and/or structured to carry out operations/functions concurrently and/or in series. Moreover, in some examples, some or all of the circuitry of FIG. 27 may be implemented within one or more virtual machines and/or containers executing on the microprocessor 3000 of FIG. 30.

In some examples, the programmable circuitry 2912 of FIG. 29 may be in one or more packages. For example, the microprocessor 3000 of FIG. 30 and/or the FPGA circuitry 3100 of FIG. 31 may be in one or more packages. In some examples, an XPU may be implemented by the programmable circuitry 2912 of FIG. 29, which may be in one or more packages. For example, the XPU may include a CPU (e.g., the microprocessor 3000 of FIG. 30, the CPU 3120 of FIG. 31, etc.) in one package, a DSP (e.g., the DSP 3122 of FIG. 31) in another package, a GPU in yet another package, and an FPGA (e.g., the FPGA circuitry 3100 of FIG. 31) in still yet another package.

Example methods, apparatus, systems, and articles of manufacture to compact rear mounted modular heat exchangers are disclosed herein. Further examples and combinations thereof include the following:

Example 1 includes an apparatus comprising a heat exchanger having an air flow inlet and an air flow outlet, a holder frame to receive a component of a server chassis, and a bracket coupled to the holder frame, the bracket to retain the heat exchanger adjacent a rear of the server chassis.

Example 2 includes the apparatus of example 1, wherein the heat exchanger includes a body defining an interior, the air flow inlet to receive an exhaust flow of air from the server chassis, the air flow outlet defining a first flow path with the air flow inlet that passes through the interior, and a tube at least partially disposed within the interior, the tube defining a second flow path between the air flow inlet and the air flow outlet, the tube to receive liquid coolant.

Example 3 includes the apparatus of example 1, further including a duct to direct an exhaust flow from the server chassis to the heat exchanger, the duct including a duct inlet defining a first plane, and a duct outlet defining a second plane, the second plane having a smaller area than the first plane.

Example 4 includes the apparatus of example 3, wherein the bracket is to be disposed adjacent a rear slot of the server chassis, the duct inlet adjacent to the server chassis via the coupling of the bracket to the heat exchanger and the server chassis.

Example 5 includes the apparatus of example 3, wherein the duct includes a first plate extending from the duct outlet away from the duct inlet, the first plate coupled to the heat exchanger, and a second plate extending from the duct outlet away from the duct inlet, the second plate parallel to the first plate, the second plate coupled to the heat exchanger.

Example 6 includes the apparatus of example 5, wherein the duct further includes a flow conduit including a planar first side wall, and a second side wall including a corner.

Example 7 includes the apparatus of example 6, wherein the first plate, the second plate, and the flow conduit are an integral component.

Example 8 includes the apparatus of example 5, wherein the heat exchanger is disposed between the first plate and the second plate.

Example 9 includes the apparatus of example 1, wherein the component is a power supply assembly of the server chassis.

Example 10 includes the apparatus of example 1, wherein the holder frame and the bracket are integral, the holder frame disposed within the server chassis, and the bracket protruding from the server chassis.

Example 11 includes a server chassis comprising a frame dimensioned to be supported in a server rack, a compute unit disposed within the frame, a power supply to supply power to the compute unit, the power supply including an exhaust outlet, and a heat exchanger supported by the frame, the heat exchanger disposed downstream in a fluid pathway associated with the exhaust outlet, the heat exchanger including an internal flow path to receive liquid coolant.

Example 12 includes the server chassis of example 11, wherein the exhaust outlet is a first exhaust outlet, the power supply is a first power supply, the heat exchanger is a first heat exchanger, the fluid pathway is a first fluid pathway, and the server chassis further includes a second power supply, a second exhaust outlet associated with the second power supply, and a second heat exchanger disposed downstream of a second fluid pathway associated with the second exhaust outlet.

Example 13 includes the server chassis of example 12, wherein the internal flow path is a first internal flow path, the second heat exchanger includes a second internal flow path, the first internal flow path and the second internal flow path to receive coolant from a coolant distribution unit associated with the server chassis.

Example 14 includes the server chassis of example 11, wherein the exhaust outlet is a first exhaust outlet, the fluid pathway is a first fluid pathway, the power supply is a first power supply, and the server chassis further includes a second power supply, and a second exhaust outlet associated with the second power supply, the heat exchanger disposed downstream of a second fluid pathway associated with the second exhaust outlet.

Example 15 includes the server chassis of example 11, further including a liquid cooling system to cool the compute unit, the liquid cooling system fluidly coupled to a manifold, the manifold fluidly coupled to the internal flow path of the heat exchanger.

Example 16 includes the server chassis of example 11, wherein the frame defines an interior of the server chassis, the power supply to be disposed within the interior, the compute unit to be disposed within the interior, and the heat exchanger to be external to the interior.

Example 17 includes a non-transitory machine readable storage medium comprising instructions to cause programmable circuitry to at least access sensor data from a sensor associated with a server chassis, determine a cooling demand of a power supply of the server chassis based on the sensor data, and modify, based on the cooling demand, a flow rate of a liquid coolant through a heat exchanger supported by the server chassis, the heat exchanger disposed external to the server chassis downstream of an exhaust of the power supply.

Example 18 includes the non-transitory machine readable storage medium of example 17, wherein the power supply is a first power supply, the heat exchanger is a first heat exchanger, the cooling demand is a first cooling demand, the flow rate is a first flow rate, the exhaust is a first exhaust, and the instructions cause the programmable circuitry to determine a second cooling demand of a second power supply of the server chassis based on the sensor data, and modify, based on the second cooling demand, a second flow rate of the liquid coolant through a second heat exchanger, the second heat exchanger positioned downstream of a second exhaust of the second power supply.

Example 19 includes the non-transitory machine readable storage medium of example 17, wherein instructions cause the programmable circuitry to modify the flow rate such that the heat exchanger exhausts air at a temperature substantially equal to an ambient temperature of an environment surrounding the server chassis.

Example 20 includes the non-transitory machine readable storage medium of example 17, wherein the instructions cause the programmable circuitry to modify the flow rate via at least one of a pump or a valve.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a heat exchanger having an air flow inlet and an air flow outlet;
a holder frame to receive a component of a server chassis; and
a bracket coupled to the holder frame, the bracket to retain the heat exchanger adjacent a rear of the server chassis.

2. The apparatus of claim 1, wherein the heat exchanger includes:
a body defining an interior, the air flow inlet to receive an exhaust flow of air from the server chassis, the air flow outlet defining a first flow path with the air flow inlet that passes through the interior; and
a tube at least partially disposed within the interior, the tube defining a second flow path between the air flow inlet and the air flow outlet, the tube to receive liquid coolant.

3. The apparatus of claim 1, further including a duct to direct an exhaust flow from the server chassis to the heat exchanger, the duct including:
a duct inlet defining a first plane; and
a duct outlet defining a second plane, the second plane having a smaller area than the first plane.

4. The apparatus of claim 3, wherein the bracket is to be disposed adjacent a rear slot of the server chassis, the duct inlet adjacent to the server chassis via the coupling of the bracket to the heat exchanger and the server chassis.

5. The apparatus of claim 3, wherein the duct includes:
a first plate extending from the duct outlet away from the duct inlet, the first plate coupled to the heat exchanger; and
a second plate extending from the duct outlet away from the duct inlet, the second plate parallel to the first plate, the second plate coupled to the heat exchanger.

6. The apparatus of claim 5, wherein the duct further includes a flow conduit including:
a planar first side wall; and
a second side wall including a corner.

7. The apparatus of claim 6, wherein the first plate, the second plate, and the flow conduit are an integral component.

8. The apparatus of claim 5, wherein the heat exchanger is disposed between the first plate and the second plate.

9. The apparatus of claim 1, wherein the component is a power supply assembly of the server chassis.

10. The apparatus of claim 1, wherein the holder frame and the bracket are integral, the holder frame disposed within the server chassis, and the bracket protruding from the server chassis.

11. A server chassis comprising:
a frame dimensioned to be supported in a server rack;
a compute unit disposed within the frame;
a power supply to supply power to the compute unit, the power supply including an exhaust outlet; and
a heat exchanger supported by the frame, the heat exchanger disposed downstream in a fluid pathway associated with the exhaust outlet, the heat exchanger including an internal flow path to receive liquid coolant.

12. The server chassis of claim 11, wherein the exhaust outlet is a first exhaust outlet, the power supply is a first power supply, the heat exchanger is a first heat exchanger, the fluid pathway is a first fluid pathway, and the server chassis further includes:
a second power supply;
a second exhaust outlet associated with the second power supply; and
a second heat exchanger disposed downstream of a second fluid pathway associated with the second exhaust outlet.

13. The server chassis of claim 12, wherein the internal flow path is a first internal flow path, the second heat exchanger includes a second internal flow path, the first internal flow path and the second internal flow path to receive coolant from a coolant distribution unit associated with the server chassis.

14. The server chassis of claim 11, wherein the exhaust outlet is a first exhaust outlet, the fluid pathway is a first fluid pathway, the power supply is a first power supply, and the server chassis further includes:
a second power supply; and
a second exhaust outlet associated with the second power supply, the heat exchanger disposed downstream of a second fluid pathway associated with the second exhaust outlet.

15. The server chassis of claim 11, further including a liquid cooling system to cool the compute unit, the liquid cooling system fluidly coupled to a manifold, the manifold fluidly coupled to the internal flow path of the heat exchanger.

16. The server chassis of claim 11, wherein the frame defines an interior of the server chassis, the power supply to be disposed within the interior, the compute unit to be disposed within the interior, and the heat exchanger to be external to the interior.

17. A non-transitory machine readable storage medium comprising instructions to cause programmable circuitry to at least:
access sensor data from a sensor associated with a server chassis;
determine a cooling demand of a power supply of the server chassis based on the sensor data; and
modify, based on the cooling demand, a flow rate of a liquid coolant through a heat exchanger supported by the server chassis, the heat exchanger disposed external to the server chassis downstream of an exhaust of the power supply.

18. The non-transitory machine readable storage medium of claim 17, wherein the power supply is a first power supply, the heat exchanger is a first heat exchanger, the cooling demand is a first cooling demand, the flow rate is a first flow rate, the exhaust is a first exhaust, and the instructions cause the programmable circuitry to:
determine a second cooling demand of a second power supply of the server chassis based on the sensor data; and
modify, based on the second cooling demand, a second flow rate of the liquid coolant through a second heat exchanger, the second heat exchanger positioned downstream of a second exhaust of the second power supply.

19. The non-transitory machine readable storage medium of claim 17, wherein instructions cause the programmable circuitry to modify the flow rate such that the heat exchanger exhausts air at a temperature substantially equal to an ambient temperature of an environment surrounding the server chassis.

20. The non-transitory machine readable storage medium of claim 17, wherein the instructions cause the programmable circuitry to modify the flow rate via at least one of a pump or a valve.
